(19) United States
(12) Patent Application Publication
(10) Pub. No.: US 2023/0223494 A1
(43) Pub. Date: Jul. 13, 2023

(54) LIGHT EMITTING DIODES AND METHOD OF MAKING THEREOF BY SELECTIVELY GROWING ACTIVE LAYERS FROM TRENCH SEPARATED AREAS

(71) Applicant: NANOSYS, INC., Milpitas, CA (US)

(72) Inventors: Zhen CHEN, Dublin, CA (US); Saket CHADDA, San Jose, CA (US); Shuke YAN, San Jose, CA (US)

(21) Appl. No.: 18/150,976

(22) Filed: Jan. 6, 2023

Related U.S. Application Data
(60) Provisional application No. 63/299,245, filed on Jan. 13, 2022.

(51) Int. Cl. H01L 33/32; H01L 33/00; H01L 33/62; H01L 33/06; H01L 33/38; H01L 25/075

(52) U.S. Cl. CPC H01L 33/32; H01L 33/007; H01L 33/0093; H01L 33/62; H01L 33/06; H01L 33/382; H01L 25/0753; H01L 2933/0016

(57) ABSTRACT

A method of forming light emitting diodes includes forming a first-conductivity-type compound semiconductor layer over a substrate, etching the first-conductivity-type compound semiconductor layer to form a first pillar structure and a second pillar structure without exposing the substrate between the first and the second pillar structures, selectively growing a semiconductor active layer over the first and the second pillar structures, and selectively growing a second-conductivity-type compound semiconductor layer on the semiconductor active layer.

### FIELD

This disclosure relates to light emitting devices, and particularly to light emitting diodes that are selectively grown from areas separated by trenches and methods of fabricating the same.

### BACKGROUND

Light emitting devices are used in electronic displays, such as backlights in liquid crystal displays located in laptops or televisions. Light emitting devices include light emitting diodes (LEDs) and various other types of electronic devices configured to emit light.

For light emitting devices, such as light emitting diodes (LED), the emission wavelength is determined by the band gap of the active region of the LED together with thickness determined confinement effects. Often the active region includes one or more bulk semiconductor layers or quantum wells (QW). For III-nitride based LED devices, such as GaN based devices, the active region (e.g., bulk semiconductor layer or QW well layer) material may be ternary, such as InₓGa₁₋ₓN, where 0<x<1.

The band gap of such III-nitride materials is dependent on the amount of In incorporated in the active region. Higher indium incorporation will yield a smaller band gap and thus longer wavelength of the emitted light. As used herein, the term “wavelength” refers to the peak emission wavelength of the LED. It should be understood that a typical emission spectra of a semiconductor LED is a narrow band of wavelength centered around the peak wavelength.

### SUMMARY

An embodiment method of forming light emitting diodes includes forming a first-conductivity-type compound semiconductor layer over a substrate, etching the first-conductivity-type compound semiconductor layer to form a first pillar structure and a second pillar structure without exposing the substrate between the first and the second pillar structures, selectively growing a semiconductor active layer over the first and the second pillar structures, and selectively growing a second-conductivity-type compound semiconductor layer on the semiconductor active layer.

An embodiment light emitting diode structure includes a first light emitting diode comprising a first portion of a first-conductivity-type compound semiconductor layer, a first portion of a semiconductor active layer located over the first portion of the first-conductivity-type compound semiconductor layer, and a first portion of a second-conductivity-type compound semiconductor layer located over the first portion of the semiconductor active layer; a second light emitting diode comprising a second portion of the first-conductivity-type compound semiconductor layer, a second portion of the semiconductor active layer located over the second portion of the first-conductivity-type compound semiconductor layer, and a second portion of the second-conductivity-type compound semiconductor layer located over the second portion of the semiconductor active layer; a trench separating the first light emitting diode and the second light emitting diode; and a third portion of the semiconductor active layer and a third portion of the second-conductivity-type compound semiconductor layer located in the trench, wherein a top surface of the third portion second-conductivity-type compound semiconductor layer is located below the first and the second portions of the semiconductor active layer.

### BRIEF DESCRIPTION OF THE DRAWINGS

FIG. 1 is a vertical cross-sectional view of an intermediate structure that may be used in the formation of LED structures, according to various embodiments.

FIG. 2 is a vertical cross-sectional view of a further intermediate structure that may be used in the formation of LED structures, according to various embodiments.

FIG. 3 is a vertical cross-sectional view of a further intermediate structure that may be used in the formation of LED structures, according to various embodiments.

FIG. 4 is a vertical cross-sectional view of a further intermediate structure that may be used in the formation of LED structures, according to various embodiments.

FIG. 5 is a vertical cross-sectional view of a further intermediate structure that may be used in the formation of LED structures, according to various embodiments.

FIG. 6 is a vertical cross-sectional view of a further intermediate structure that may be used in the formation of LED structures, according to various embodiments.

FIG. 7 is a vertical cross-sectional view of a further intermediate structure that may be used in the formation of LED structures, according to various embodiments.

FIG. 8 is a vertical cross-sectional view of a further intermediate structure that may be used in the formation of LED structures, according to various embodiments.

FIG. 9 is a vertical cross-sectional view of a further intermediate structure that may be used in the formation of LED structures, according to various embodiments.

FIG. 10 is a vertical cross-sectional view of a further intermediate structure that may be used in the formation of LED structures, according to various embodiments.

FIG. 11 is a vertical cross-sectional view of LED structures, according to various embodiments.

FIG. 12A is a vertical cross-sectional view of a further intermediate structure that may be used in the formation of LED structures, according to various embodiments.

FIG. 12B is a vertical cross-sectional view of a further intermediate structure that may be used in the formation of LED structures, according to various embodiments.

FIG. 12C is a vertical cross-sectional view of a further intermediate structure that may be used in the formation of LED structures, according to various embodiments.

FIG. 13A is a vertical cross-sectional view of a further intermediate structure that may be used in the formation of LED structures, according to various embodiments.

FIG. 13B is a vertical cross-sectional view of a further intermediate structure that may be used in the formation of LED structures, according to various embodiments.

FIG. 14 illustrates a vertical cross sectional view of a source coupon including a plurality of light emitting diodes that may be transferred to a backplane, according to various embodiments.

FIG. 15A is a vertical cross sectional view of an intermediate structure having the source coupon positioned over a backplane prior to attachment of light emitting diodes to the backplane, according to various embodiments.

FIG. 15B is a vertical cross sectional view of a further intermediate structure in which the backplane and the first source coupon are brought into contact with one another such that each facing pair of a diode-side bonding material portion and a backplane-side bonding material portion contact each other, according to various embodiments.

FIG. 15C is a vertical cross sectional view of the intermediate structure of FIG. 15B in which sequential laser irradiation process may be performed to selectively irradiate each buffer layer that overlies a first light emitting diode to be subsequently transferred to the backplane with a detachment laser beam, according to various embodiments.

FIG. 15D is a vertical cross sectional view of the intermediate structure of FIG. 15B in which the liquid gallium-rich drops have solidified into solid gallium-rich material portions, according to various embodiments.

FIG. 15E is a vertical cross sectional view of the intermediate structure of FIG. 15B in which the backplane and the first source coupon are pressed against one another with a greater force to thereby induce deformation of the bonding material portions, according to various embodiments.

FIG. 15F is a vertical cross sectional view of the intermediate structure of FIG. 15B in which a sequential localized laser irradiation process may be performed to induce reflow and subsequent bonding of each mating pair of a diode-side bonding material portion and a backplane-side bonding material portion, according to various embodiments.

FIG. 15G is a vertical cross sectional view of a further intermediate structure in which the first source coupon and the backplane are removed from the clamp 400 and heated, according to various embodiments.

FIG. 16A is a vertical cross sectional view of a further intermediate structure in which a second source coupon may be provided, which includes second light emitting diodes located on a second substrate, according to various embodiments.

FIG. 16B is a vertical cross sectional view of a further intermediate structure in which the backplane and the second source coupon are brought into contact with one another such that each facing pair of a diode-side bonding material portions and a backplane-side bonding material portions contact each other, according to various embodiments.

FIG. 16C is a vertical cross sectional view of a further intermediate structure in which the second source coupon is separated from the backplane after a first subset of the second light emitting diodes has been bonded to the backplane, according to an embodiment.

FIG. 17 is a vertical cross sectional view of a further intermediate structure in which a subset of third light emitting diodes has been bonded to the backplane, according to an embodiment.

### DETAILED DESCRIPTION

A display device, such as a direct view display may be formed from an ordered array of pixels. Each pixel may include a set of subpixels that emit light at a respective peak wavelength. For example, a pixel may include a red subpixel, a green subpixel, and a blue subpixel. Each subpixel may include one or more light emitting diodes that emit light of a particular wavelength. A traditional arrangement is to have red, green, and blue (RGB) subpixels within each pixel. Each pixel is driven by a backplane circuit such that any combination of colors within a color gamut may be shown on the display for each pixel. The display panel may be formed by a process in which LED subpixels are soldered to, or otherwise electrically attached to, a bond pad located on a backplane. The bond pad is electrically driven by the backplane circuit and other driving electronics.

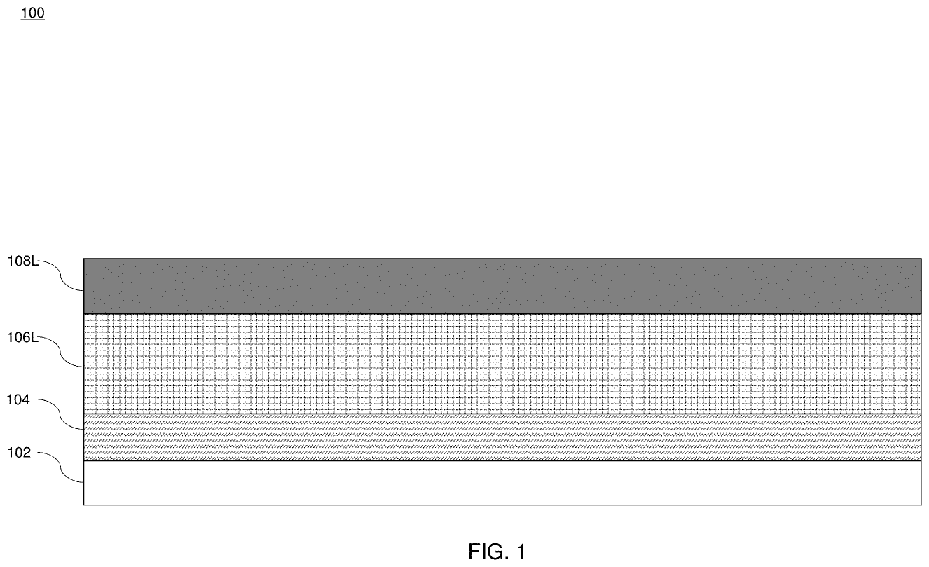

FIG. 1 is a vertical cross-sectional view of an intermediate structure 100 that may be used in the formation of LED structures, according to various embodiments. The intermediate structure 100 may include a support substrate 102 and a buffer layer 104. The buffer layer 104 may be a doped single crystalline compound semiconductor layer such as a doped single crystalline III-V compound semiconductor layer (e.g., a n-doped single crystalline GaN layer). The buffer layer 104 may have a doping of a first conductivity type, which may be p-type or n-type. The support substrate 102 may be any single crystalline substrate (such as a single crystalline sapphire substrate) that may function as an epitaxial growth template for the buffer layer 104. In one embodiment, the interface between the support substrate 102 and the buffer layer 104 may be planar or non-planar (e.g., the interface may be textured if the support substrate includes a patterned sapphire substrate (PSS)).

Any single crystalline material layer may be employed for the support substrate 102 provided that epitaxial growth of a compound semiconductor material, such as a III-V compound semiconductor material, from the top surface of the single crystalline material layer is possible. The support substrate 102 may include a single crystalline material such as Al₂O₃ (sapphire) using either basal plane (i.e., c-plane) or r-plane growing surfaces, diamond, Si, Ge, GaN, AlN, SiC in both wurtzite (α) and zincblende (β) forms, InN, GaP, GaAsP, GaAs, InP, ZnO, ZnS, and ZnSe. For example, the support substrate 102 may include sapphire (i.e., single crystalline aluminum oxide) with a suitable surface orientation.

The support substrate 102 may include a PSS having a patterned (e.g., rough) growth surface. Bumps, dimples, and/or angled cuts may, or may not, be provided on the top surface of the support substrate 102 to facilitate epitaxial growth of the single crystalline compound semiconductor material of the buffer layer 104, to facilitate separation of the buffer layer 104 from the support substrate 102 in a subsequent separation process and/or to improve the light extraction efficiency through the buffer layer 104. If bumps and/or dimples are provided on the top surface of the support substrate 102, the lateral dimensions of each bump or each dimple may be in a range from 1.5 microns to 6 microns, although lesser and greater lateral dimensions may also be employed. The center-to-center distance between neighboring pairs of bumps or dimples may be in a range from 3 microns to 15 microns, although lesser and greater distances may also be employed. Various geometrical configurations may be employed for arrangement of the bumps or dimples. The height of the bumps and/or the depth of the dimples may be on the order of 1 microns to 3 microns, although lesser and greater heights and/or depths may also be employed.

The buffer layer 104 may include a single crystalline compound semiconductor material such as a III-V compound semiconductor material. The buffer layer 104 may have a thickness of 1 to 2 microns. The deposition process for forming the buffer layer 104 may employ various techniques including metal organic chemical vapor deposition (MOCVD), metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), or atomic layer deposition (ALD). The buffer layer 104 may have a constant or a graded composition such that the composition of the buffer layer 104 at the interface with the support substrate 102 provides a substantial lattice matching with the two-dimensional lattice structure of the top surface of the support substrate 102. The composition of the buffer layer 104 may be gradually changed during the deposition process. If a PSS support substrate 102 is used, then the bottom surface of the buffer layer 104 may be a patterned (i.e., rough) surface.

The materials that may be employed for a bottom portion of the buffer layer 104 may be, for example, Ga_{1-w} In_{w} As₁ N_{1-y} in which w and y may be zero (i.e., the buffer layer 104 may comprise GaN) and are selected to match the lattice constant of the top surface of the support substrate 102. Optionally, Al or P may also be included in the material for the bottom portion of the buffer layer, in which case the bottom portion of the buffer layer 104 may include Ga_{1-w-z} In_{w} Al_{z} N_{1-x-y} As_{y}Pₓ that matches the lattice constant of the top surface of the support substrate 102. The materials that may be employed for a top portion of the buffer layer 104 may include, but are not limited to, direct band gap III-V compound materials such as gallium nitride (GaN), aluminum nitride (AlN), gallium phosphide (GaP), gallium arsenide (GaAs), gallium antimonide (GaSb), indium nitride (InN), indium phosphide (InP), indium arsenide (InAs), and indium antimonide (InSb).

The composition of the buffer layer 104 may gradually change between the bottom portion of the buffer layer 104 and the top portion of buffer layer 104 such that dislocations caused by a gradual lattice parameter change along the growth direction (vertical direction) does not propagate to the top surface of the buffer layer 104. In one embodiment, a thin bottom portion of the buffer layer 104 less than 1 micron in thickness may be undoped or doped at a low concentration of silicon.

The intermediate structure 100 may further include a continuous first-conductivity-type semiconductor material layer 106L, which may be formed as a blanket material layer having a uniform thickness and continuously extending over the entire area of the buffer layer 104. As used herein, a “continuous” element refers to a unitary element that extends continuously between each segment of the element without a discontinuity. The continuous first-conductivity-type semiconductor material layer 106L may include a doped single crystalline compound semiconductor material having a doping of the first conductivity type, that is, the conductivity type of doping of the buffer layer 104.

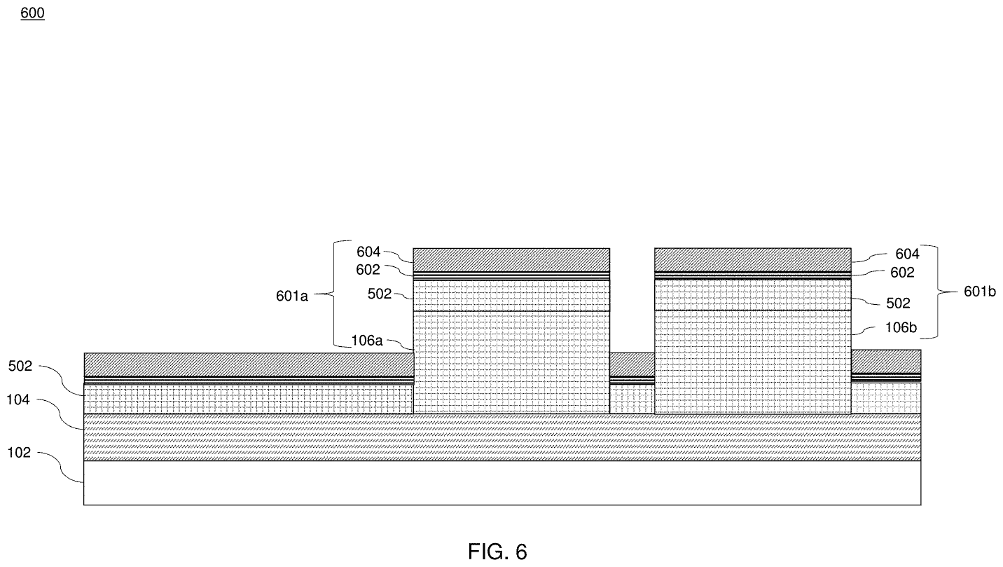

The material of the continuous first-conductivity-type semiconductor material layer 106L may be the same as, or may be different from, the material of the buffer layer 104, and may be epitaxially aligned with the material of the buffer layer 104. In one embodiment, the material of the continuous first-conductivity-type semiconductor material layer 106L may be selected to match the average lattice constant of the material layers to be subsequently employed in an active layer 602 (e.g., see FIG. 6 and related description, below), and to reduce mechanical stress within the active layer 602. For example, the material of the continuous first-conductivity-type semiconductor material layer 106L may include n-type gallium nitride. In one embodiment, the first conductivity type may be n-type. In another embodiment, the first conductivity type may be p-type. The epitaxial growth process that grows the continuous first-conductivity-type semiconductor material layer 106L may be selective or non-selective. The continuous first-conductivity-type semiconductor material layer 106L may be formed by a deposition process that may employ any of MOCVD, MOVPE, MBE, HYPE, LPE, MOMBE, or ALD. In an alternative embodiment, instead of a separate buffer layer 104 and first-conductivity-type semiconductor material layer 106L, a single first-conductivity-type semiconductor material layer 106L may be formed directly on the substrate 102, and the buffer layer 104 may be omitted.

The intermediate structure 100 may further include an optional continuous masking layer 108L formed over the continuous first-conductivity-type semiconductor material layer 106L. The continuous masking layer 108L may include a hard mask material, such as silicon nitride, silicon carbide, silicon nitride carbide, or a dielectric metal oxide (such as aluminum oxide, titanium oxide, tantalum oxide, etc.). Other embodiments may include various other materials for the continuous masking layer 108L (e.g., a photoresist). The continuous masking layer 108L may be deposited by a conformal or non-conformal deposition process. In one embodiment, the continuous masking layer 108L may be deposited by chemical vapor deposition (CVD), ALD, or physical vapor deposition (PVD). The thickness of the continuous masking layer 108L may be in a range from approximately 2 nm to approximately 20 nm, such as from approximately 3 nm to approximately 12 nm, although smaller and larger thicknesses may also be used.

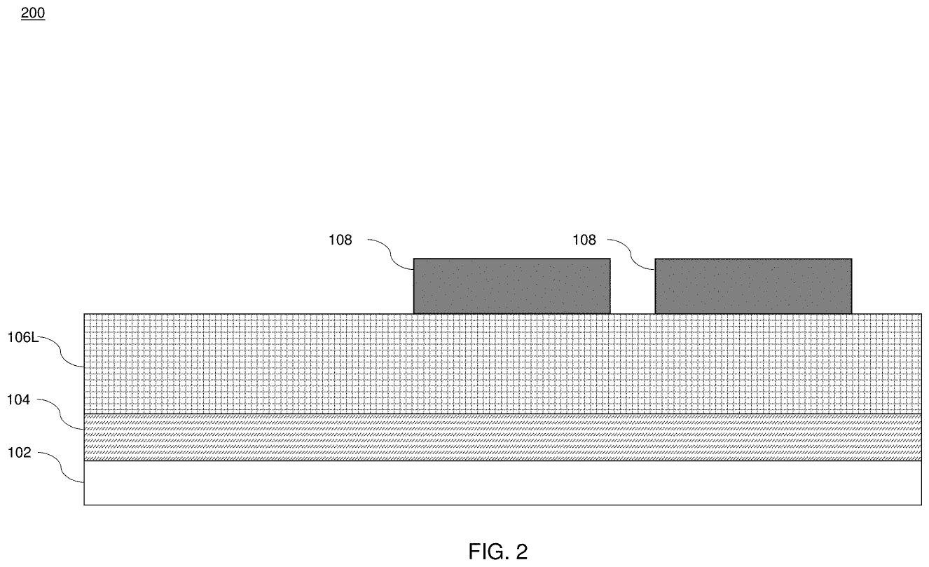

FIG. 2 is a vertical cross-sectional view of a further intermediate structure 200 that may be used in the formation of LED structures, according to various embodiments. The intermediate structure 200 may be formed by patterning the continuous masking layer 108L to form a patterned mask 108. In this regard, a photoresist (not shown) may be formed over the top surface of the continuous masking layer 108L shown in FIG. 1. The photoresist may then be patterned using photolithographic techniques to form a patterned photoresist. The patterned photoresist may then be used as a mask while patterning the continuous masking layer 108L. Patterning of the continuous masking layer 108L may be performed by using an anisotropic etch process. After etching, any residual photoresist may be removed by ashing or dissolution with a solvent. Alternatively, if the continuous masking layer 108L comprises photoresist, then it may be directly exposed and patterned using photolithographic techniques to form the patterned mask 108.

The resulting patterned mask 108 may include a plurality of separate structures (while two are shown in this example, there may be thousands or millions or separate structures). The separate structures serve as an etch mask for patterning the continuous first-conductivity-type semiconductor material layer 106L in further processing steps, as described in greater detail below. In one embodiment, the discrete portions of the patterned mask 108 may be arranged as a two-dimensional periodic array or a one-dimensional periodic array. The horizontal cross-sectional shape of each discrete portion of the patterned mask 108 may be circular, rectangular, elliptical, polygonal, of a rounded polygonal shape, or of any generally two-dimensional closed curvilinear shape having a periphery. The lateral width of each discrete portion of the patterned mask 108 may be 1 to 50 microns, such as 5 to 20 microns.

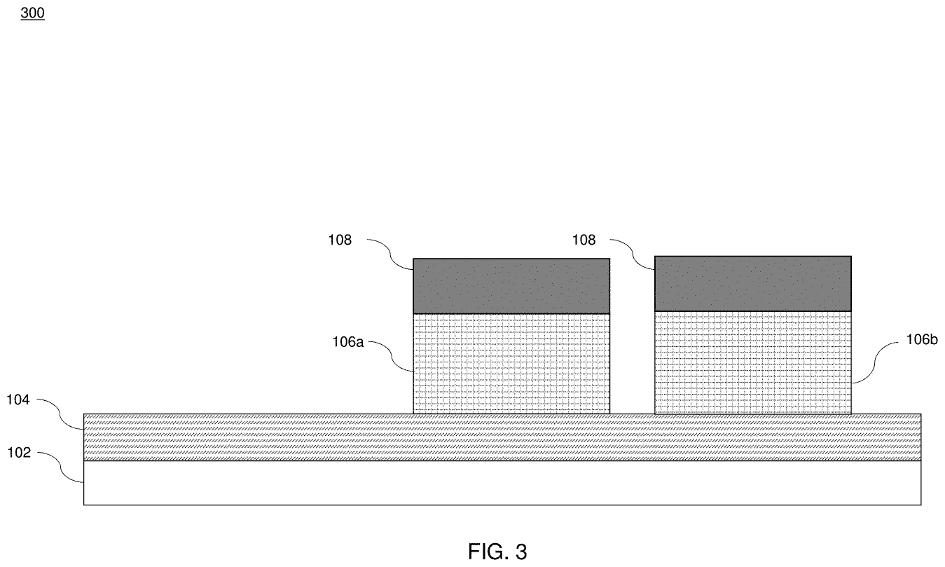

FIG. 3 is a vertical cross-sectional view of a further intermediate structure 300 that may be used in the formation of LED structures, according to various embodiments. The intermediate structure 300 may be formed by etching the continuous first-conductivity-type semiconductor material layer 106L of FIG. 2 using the patterned mask 108. In this regard, an etch process may include, and/or may consist of, at least one anisotropic etch step (such as at least one reactive ion etch process). The etch process may be conducted without exposing a surface of the substrate 102. In one embodiment, the etch process may etch through portions of the continuous first-conductivity-type semiconductor material layer 106L until a top surface of the buffer layer 104 is physically exposed. In an alternative embodiment, the etch process may be a timed etch process which terminates after portions of the continuous first-conductivity-type semiconductor material layer 106L that are not masked by the patterned mask 108 are etched by the etch process through only a part of their thickness. In this case, horizontal portions of the continuous first-conductivity-type semiconductor material layer 106L are exposed between the patterned mask 108 portions. In this alternative embodiment, the buffer layer 104 may be present or omitted. In another alternative embodiment in which the buffer layer 104 is present, the etch may be continued to partially etch through the thickness of the buffer layer 104 without reaching the surface of the substrate 102. In general at least one micron, such as one to two microns of semiconductor material may remain over the surface of the substrate 102.

After the etch, the unetched portions of the continuous first-conductivity-type semiconductor material layer 106L form a plurality of pillar structures. In this example embodiment, the plurality of pillar structures may include a first pillar structure 106a and a second pillar structure 106b. Each of the first pillar structure 106a and the second pillar structure 106b may include vertical walls and may have a lateral extension that is in a range from 1 micron to 50 microns, such as from 5 microns to 20 microns. Each of the first pillar structure 106a and the second pillar structure 106b may have a height that is comparable to, or larger than the lateral dimension. For example, in an embodiment, the first pillar structure 106a and the second pillar structure 106b may have a height that is in a range from 10 microns to 50 microns. The vertical sidewalls of the pillar structures 106a and 106b may be damaged by the reactive ion etching and may contain dangling bonds.

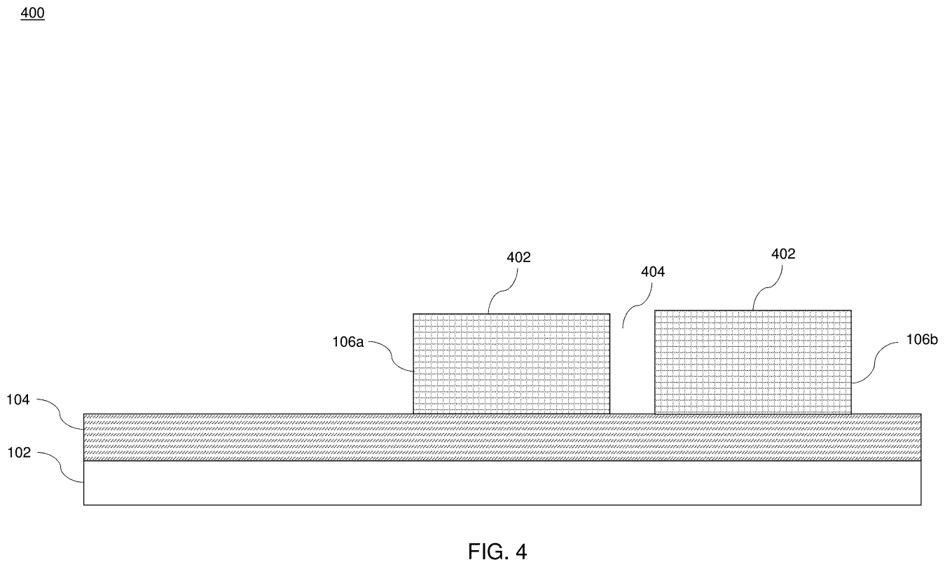

FIG. 4 is a vertical cross-sectional view of a further intermediate structure 400 that may be used in the formation of LED structures, according to various embodiments. The intermediate structure 400 may be formed from the intermediate structure 300 of FIG. 3 by removing the patterned mask 108. The patterned mask 108 may be removed by selective wet or dry etching (e.g., if it comprises a hard mask) or by ashing (e.g., if it comprises photoresist or a carbon hard mask). The first pillar structure 106a and a second pillar structure 106b may each have a top surface 402 that is oriented parallel to a c-plane surface of the first-conductivity-type semiconductor material. For example, the top surface 402 may include a c-plane (e.g., (0001) plane family) gallium nitride surface. As such, the top surface 402 of each of the first pillar structure 106a and the second pillar structure 106b may form a template for selective epitaxial growth of high quality active material layers of a LED. The first pillar structure 106a and the second pillar structure 106b are laterally separated by a trench 404.

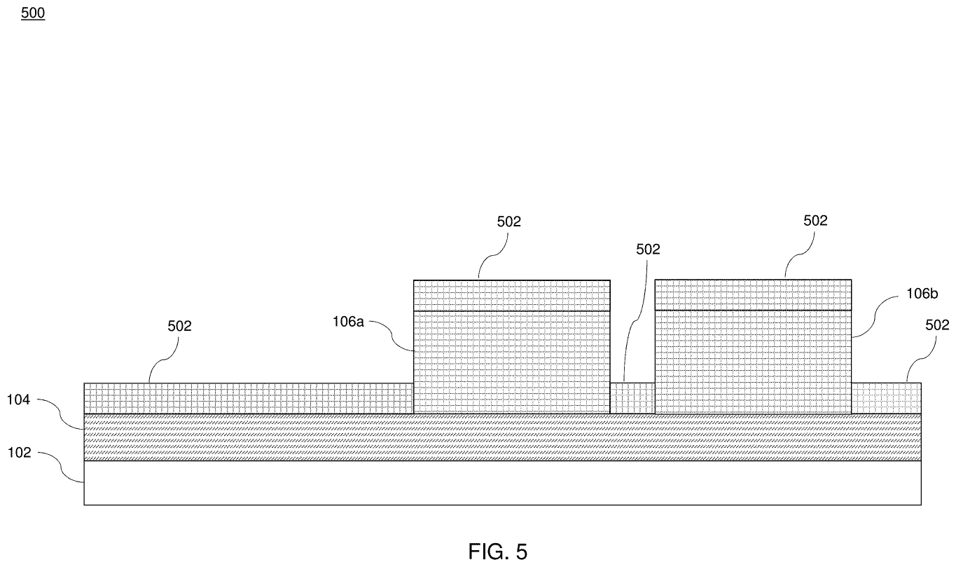

FIG. 5 is a vertical cross-sectional view of a further intermediate structure 500 that may be used in the formation of LED structures, according to various embodiments. The intermediate structure 500 may be formed by selective epitaxial growth of a regrowth layer 502 on the top surfaces 402 of the pillar structures 106a and 106b. In this regard, the regrowth layer 502 may include an additional layer of doped semiconductor material that may be formed by any selective epitaxial deposition process employing any of MOCVD, MOVPE, MBE, HYPE, LPE, MOMBE, or ALD. The regrowth layer 502 may, or may not, include the same doped semiconductor material as the first-conductivity-type semiconductor material layer that forms the first pillar structure 106a and the second pillar structure 106b. The regrowth layer 502 may be chosen to be lattice matched with the first-conductivity-type semiconductor material layer that forms the first pillar structure 106a and the second pillar structure 106b. The regrowth layer 502 may include a high quality single crystalline surface with low defect density that is suitable for forming additional layers of an LED device. In one embodiment, the regrowth layer 502 may include n-type GaN layer having a c-plane top surface.

Without wishing to be bound by a particular theory, the present inventors believe that if the sapphire substrate 102 was exposed between the pillar structures 106a and 106b during the growth of the gallium containing regrowth layer 502 (e.g., a n-type GaN layer), then undesirable semiconductor edge effects may occur. Specifically, without wishing to be bound by a particular theory, the present inventors believe the exposed sapphire (or another oxide) substrate 102 may cause gallium atoms to diffuse on sidewalls of the pillar structures and cause bumps to form on the edges of the regrowth layer 502 during growth of the regrowth layer 502 on each pillar structure. The bumps may result in a non-uniform thickness of the regrowth layer 502 on each pillar structure, which may provide a non-planar top surface of the regrowth layer 502. Therefore, subsequent growth of the active layer on a non-planar top surface of the regrowth layer 502 may result in decreased quality of the active layer (e.g., non-uniform quantum well thickness and differences in conductivity and quantum efficiency between the edges and center of each active layer located over each pillar structure). However, by not exposing the substrate 102 between the pillar structures, the above noted edge effects are avoided or reduced, and the regrowth layer 502 has a more planar surface over each pillar structure. This results in a more uniform and higher quality active layer grown on the regrowth layer 502.

FIG. 6 is a vertical cross-sectional view of a further intermediate structure 600 that may be used in the formation of LED structures, according to various embodiments. The intermediate structure 600 may include an active layer 602 and a second-conductivity-type semiconductor material layer 604 formed over the first pillar structure 106a and the second pillar structure 106b. In this way, a first vertical LED 601a and a second vertical LED 601b may be formed. The first and second vertical LEDs comprise laterally separated, pillar shaped LEDs.

The active layer 602 and the second-conductivity-type semiconductor material layer 604 may comprise single crystal semiconductor materials which are selectively grown on the regrowth layer 502 using any suitable epitaxial growth method. The active layer 602 may include at least one semiconductor material that emits light upon application of a suitable electrical bias. For example, the active layer 602 may include a single or a multi-quantum well (MQW) structure that emits light upon application of an electrical bias thereacross. For example, the quantum well(s) may include indium gallium nitride well(s) located between gallium nitride or aluminum gallium nitride barrier layers. Alternatively, the active layer 602 may include any other suitable semiconductor layers or stack of layers for light emitting diode applications. The active layer 602 may be configured to emit any color light, such as blue, green, or red light.

The second-conductivity-type semiconductor material layer 604 may include a compound semiconductor material having a doping of the second conductivity type opposite to the first conductivity type. The compound semiconductor material of the second-conductivity-type semiconductor material layer 604 may be any suitable semiconductor material, such as p-type gallium nitride or aluminum gallium nitride. For example, the continuous first-conductivity-type semiconductor material layer 106L may include n-doped GaN, and the second-conductivity-type semiconductor material layer 604 may include p-doped GaN.

The combined thickness of the active layer 602 and the second-conductivity-type semiconductor material layer 604 is less than the thickness of each pillar structure (e.g., 106a or 106b). This way, the portions of the active layer 602 and the second-conductivity-type semiconductor material layer 604 deposited between the pillar structures 106a and 106b do not reach the level of the portions of the active layer 602 located on each pillar structure 106a, 106b in each vertical LED 601a, 601b. Therefore, the portions of the active layer 602 and the second-conductivity-type semiconductor material layer 604 do not short circuit the active layers 602 in each vertical LED 601a, 601b.

Since the active layer 602 and the second-conductivity-type semiconductor material layer 604 are selectively grown from the regrowth layer 502, they do not undergo a reactive ion etch. Therefore, the RIE induced sidewall damage and sidewall dangling bonds are not generated in the active layer 602 and the second-conductivity-type semiconductor material layer 604. This results in higher quality semiconductor material in the active layer 602 and improved device performance. Furthermore, since the substrate 102 is not exposed between the pillar structures during the growth of the regrowth layer 502, this may provide a regrowth layer 502 with a more planar surface over each pillar structure. This may lead to a more uniform and higher quality active layer 602 grown on the regrowth layer 502.

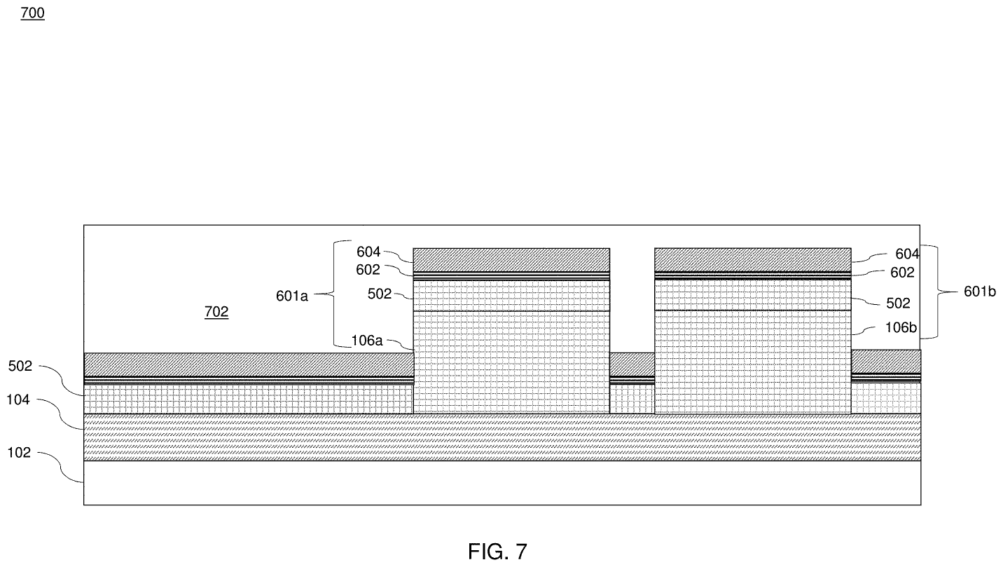

FIG. 7 is a vertical cross-sectional view of a further intermediate structure 700 that may be used in the formation of LED structures, according to various embodiments. A dielectric matrix layer 702 may be formed between the vertical LEDs 601a and 601b. The dielectric matrix layer 702 may include a planarizable passivation material such as an organic polymer or silicon oxide, or may include a self-planarizing passivation material such as flowable oxide (FOX). In embodiments in which the dielectric matrix layer 702 includes a non-planarizable dielectric material, a chemical mechanical polishing (CMP) process may be performed to provide a planar top surface. The top surface of the dielectric matrix layer 702 may be located above or co-planar with the top surface of the second-conductivity-type semiconductor material layer 604. If the top surface of the dielectric matrix layer 702 is co-planar with the top surface of the second-conductivity-type semiconductor material layer 604, then the top surface of the second-conductivity-type semiconductor material layer 604 in each vertical LED 601a and 601b is exposed in the top surface of the dielectric matrix layer 702.

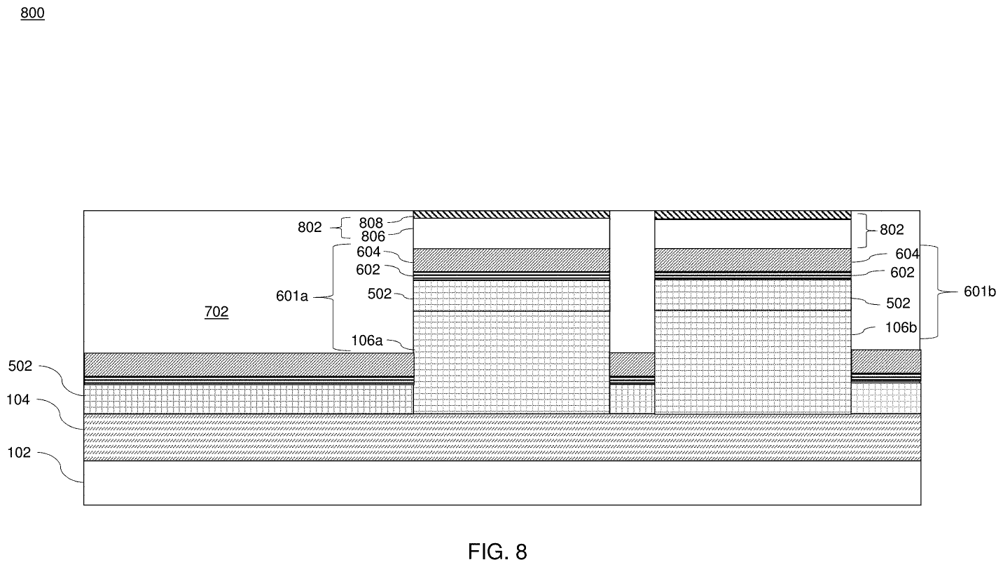

FIG. 8 is a vertical cross-sectional view of a further intermediate structure 800 that may be used in the formation of LED structures, according to various embodiments. If the top surface of the dielectric matrix layer 702 is located above the top surface of the second-conductivity-type semiconductor material layer 604, then a photolithographic patterning step is performed to form openings over each vertical LED 601a and 601b. The second-conductivity-type semiconductor material layer 604 is exposed in each opening.

Electrodes 802 are then formed over the vertical LEDs 601a and 601b. If the openings are present in the dielectric matrix layer 702, then the electrodes 802 may be formed by a damascene method. In the damascene method, the conductive material of the electrodes is formed over the top surface of the dielectric matrix layer 702 and in the openings in the dielectric matrix layer 702. The conductive material is then planarized (e.g., by CMP) to leave the conductive material electrodes 802 only in the openings in contact with the second-conductivity-type semiconductor material layer 604 of each vertical LED. If the top surface of the dielectric matrix layer 702 is co-planar with the top surface of the second-conductivity-type semiconductor material layer 604, then a continuous conductive material layer is formed over the top surface of the dielectric matrix layer 702. The continuous conductive layer is then photolithographically patterned (e.g., by photolithography and etching) to form the electrodes 802 in contact with the second-conductivity-type semiconductor material layer 604 of each vertical LED exposed in the top surface of the dielectric matrix layer 702.

The electrodes 802 may include an optional transparent conductive oxide layer 806 and an optional reflector layer 808. The transparent conductive oxide layer 806 may include a transparent conductive oxide material, such as indium tin oxide or aluminum doped zinc oxide. Alternatively, the transparent conductive oxide layer 806 may be replaced with a silver or aluminum layer, to provide a contact to a p-type semiconductor material (e.g., to layer 604 of each vertical LED). In this case, the silver or aluminum layer may function as a reflector material layer and subsequent deposition of a reflector material layer may be omitted.

The reflector layer 808 may be a metal. In one embodiment, the reflector layer 808 may include at least one material selected from silver, aluminum, copper, or gold. In one embodiment, the reflector material may be a thin film distributed Bragg reflector (DBR) with small index changes to provide better reflectivity. Thus, the DBR reflector material may include at least one conductive material and/or at least one electrically insulating material. The combination of the transparent conductive oxide layer 806 and the reflector layer 808 form a p-side electrode 802 to each vertical LED 601a and 601b.

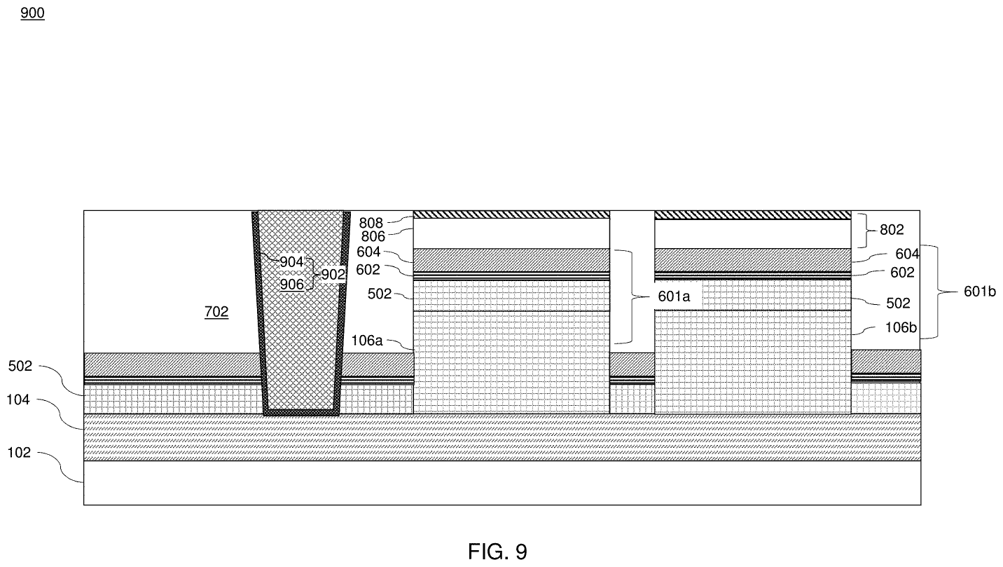

FIG. 9 is a vertical cross-sectional view of a further intermediate structure 900 that may be used in the formation of LED structures, according to various embodiments. A via cavity may be formed through the dielectric matrix layer 702. For example, a photoresist layer (not shown) may be applied over the dielectric matrix layer 702, and may be lithographically patterned to form an opening therethrough. An anisotropic etch process may be performed to etch through the dielectric matrix layer 702 until a surface of the buffer layer 104 is physically exposed to form the via cavity. In other embodiments, a plurality of via cavities may be formed such that each light emitting diode to be subsequently formed has a respective contact via structure. The photoresist layer may be subsequently removed, for example, by ashing.

At least one conductive material may be deposited in each via cavity. The at least one conductive material may include, for example, a metallic liner material such as TiN, TaN, or WN and a metallic fill material such as W, Cu, Mo, Al, Ag, Co, Au, Ni, Sn, other elemental metals, and/or alloys or combinations thereof. A CMP process and/or a selective recess etch may be performed to remove portions of the at least one conductive material from above the top surface of the dielectric matrix layer 702. A contact via structure 902 is formed within each via cavity. Each contact via structure 902 may include a metallic liner 904 that may include a remaining portion of the metallic liner material and a metallic fill material portion 906 that may include a remaining portion of the metallic fill material. Each contact via structure 902 may vertically extend through the dielectric matrix layer 702 and may contact the buffer layer 104.

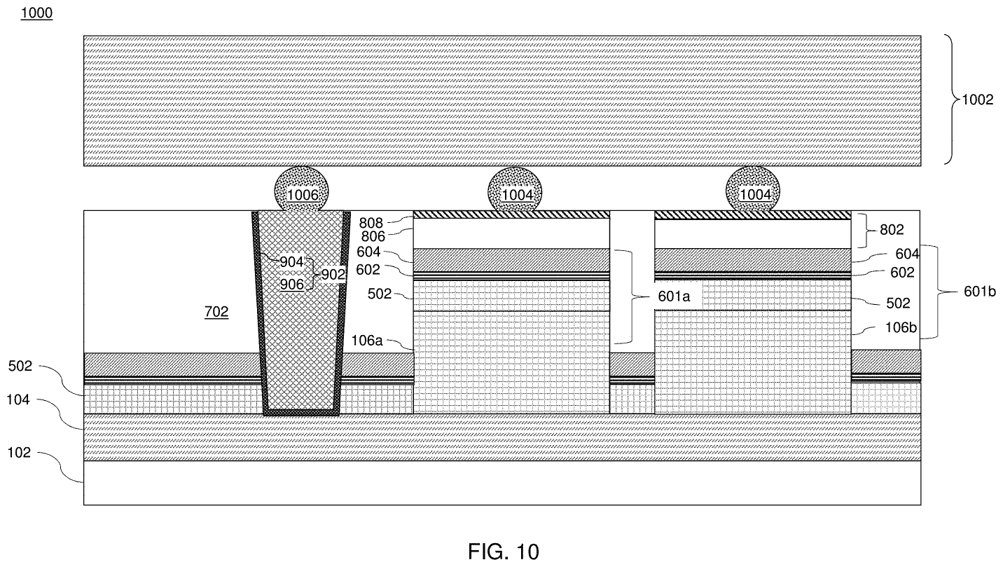

FIG. 10 is a vertical cross-sectional view of a further intermediate structure 1000 that may be used in the formation of LED structures, according to various embodiments. Conductive bonding structures 1004, 1006 may be formed on the electrodes 802 and the contact via structures 802. The conductive bonding structures 1004, 1006 may include first conductive bonding structures 1004 that are formed in electrical contact with a respective one of the p-side electrodes 802, and second conductive bonding structures 1006 that are formed in electrical contact with a respective one of the contact via structures (e.g., n-side contact via structures) 902. The conductive bonding structures 1004, 1006 may include a solder material, which may include tin, and optionally may include an alloy of tin and silver, gold, copper, bismuth, indium, zinc, and/or antimony. It is understood that the shape of the conductive bonding structures 1004, 1006, as illustrated is only schematic, and may not represent a true shape of conductive bonding structures 1004, 1006.

The conductive bonding structures 1004, 1006 may be attached (i.e., bonded) to a support substrate, such as a backplane 1002. The conductive bonding structures 1004, 1006 may be bonded to bonding pads or to bonding structures (e.g., solder balls) located on the backplane 1002. The bonding may comprise thermal (e.g. furnace anneal) bonding, laser bonding or flash lamp bonding which reflows the conductive bonding structures.

The backplane 1002 may be an active or passive matrix backplane substrate for driving the vertical LEDs 601a, 601b. As used herein, a “backplane substrate” refers to any substrate configured to affix multiple devices thereupon. The backplane 1002 may contain a backplane substrate. The backplane substrate may be a substrate onto which various devices (e.g., LEDs) may be subsequently transferred.

In one embodiment, the backplane 1002 may include a substrate including silicon, glass, plastic, and/or at least another material that may provide structural support to the devices to be subsequently transferred thereupon. In one embodiment, the backplane substrate may be a passive backplane substrate, in which metal interconnect structures (not shown) including metallization lines are present, for example, in a crisscross grid and active device circuits are not present. In another embodiment, the backplane substrate may be an active backplane substrate, which may include metal interconnect structures as a crisscross grid of conductive lines and further may include device circuitry at one or more intersections of the crisscross grid of conductive lines. The device circuitry may include one or more transistors, such as thin film transistors (TFTs).

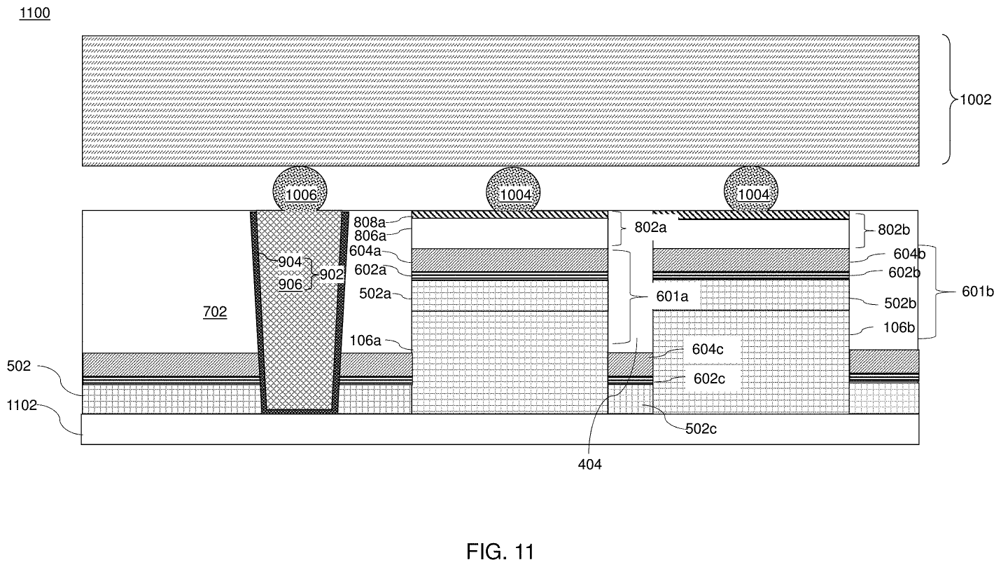

FIG. 11 is a vertical cross-sectional view of a LED structure 1100, according to various embodiments. The substrate 102 and optionally the buffer layer 104 may be removed from the LEDs 601a and 601b. The removal may be performed by laser lift off, mechanical removal and/or selective etching. The removal step may be performed before or after the bonding step shown in FIG. 10. A second electrode 1102 is deposited on the exposed bottom sides of the vertical LEDs. The second electrode 1102 may include a transparent conductive layer, such as ITO, AZO, etc. The second electrode 1102 may be a common n-side electrode for all vertical LEDs 601a, 601b in the device. The second electrode 1102 electrically contacts (e.g., directly or indirectly) the contact via structure 902, which is electrically connected to the backplane 1002. The vertical LEDs 601a, 601b comprise bottom emitting LEDs which emit radiation (e.g., visible light) through the second electrode 1102.

Each vertical light emitting diode 601a, 601b may emit the same color light (e.g., have the same peak emission wavelength) or different color light (e.g., have different peak emission wavelengths). For example, the light emitting diodes may emit one of red, green, or blue light to form an RGB display. Alternatively, a color conversion medium, such as quantum dots, a phosphor, or a dye may be provided between each light emitting diode and the observer. The color conversion medium may be provided on the opposite side of the second electrodes 1102 from the LEDs 601a, 601b. In this case, each light emitting diode may emit the same color light (e.g., blue light or UV radiation), and the color conversion medium may include red, green, and optionally blue (for UV emitting LEDs) color conversion medium to form the RGB display.

An embodiment light emitting diode structure 1100 shown in FIG. 11 includes a first light emitting diode 601a and a second light emitting diode 601b. The first LED 601a comprises a first portion 106a of a first-conductivity-type compound semiconductor layer 106L, a first portion 602a of a semiconductor active layer 602 located over the first portion 106a of the first-conductivity-type compound semiconductor layer, and a first portion 604a of a second-conductivity-type compound semiconductor layer 604 located over the first portion 602a of the semiconductor active layer.

The second LED 601b comprises a second portion 106b of the first-conductivity-type compound semiconductor layer 106L, a second portion 602b of the semiconductor active layer 602 located over the second portion 106b of the first-conductivity-type compound semiconductor layer, and a second portion 604b of the second-conductivity-type compound semiconductor layer 604 located over the second portion 602b of the semiconductor active layer. A trench 404 separates the first light emitting diode 601a and the second light emitting diode 601b.

A third portion 602c of the semiconductor active layer 602 and a third portion 604c of the second-conductivity-type compound semiconductor layer 604 are located in the trench 404. A top surface of the third portion 604c second-conductivity-type compound semiconductor layer 604 is located below the first portion 602a and the second portion 602b of the semiconductor active layer 602 in each LED 601a, 601b.

In one embodiment, a first portion 502a of a semiconductor regrowth layer 502 is located between the first portion 106a of the first-conductivity-type compound semiconductor layer 106L and the first portion 602a of the semiconductor active layer 602 in the first light emitting diode 601a. A second portion 502b of the semiconductor regrowth layer 502 is located between the second portion 106b of the first-conductivity-type compound semiconductor layer 106L and the second portion 602b of the semiconductor active layer 602 in the second light emitting diode 601b. A third portion 502c of the semiconductor regrowth layer 502 is located in the trench 404 below the third portion 602c of the semiconductor active layer 602.

In one embodiment, the semiconductor regrowth layer 502 comprises a single crystal n-type GaN layer having top c-plane surface, the first-conductivity-type compound semiconductor layer 106L includes a single crystal n-type GaN, the second-conductivity-type compound semiconductor layer 604 includes a single crystal p-type GaN, and the semiconductor active layer 602 includes at least one InGaN quantum well.

In one embodiment, first electrodes 802a, 802b are located over the respective first portion 604a and the second portion 604b second-conductivity-type compound semiconductor layer 604 in the first and the second light emitting diodes. First conductive bonding structures 1004 are electrically connected to the first electrodes 802a, 802b. A dielectric matrix layer 702 laterally surrounds the first and the second light emitting diodes 601a, 601b. A backplane 1002 is electrically connected to the first conductive bonding structures 1004.

In one embodiment, a common second electrode 1102 is located over the first and the second portions 106a, 106b of the first-conductivity-type compound semiconductor layer 106L, a contact via structure 902 vertically extends through the dielectric matrix layer 702 and electrically contacts the common second electrode 1102, and a second conductive bonding structure 1006 electrically connects the contact via structure 902 to the backplane 1002.

In one embodiment described above, the first portion 602a of the semiconductor active layer 602 lacks sidewall dangling bonds or reactive ion etch induced sidewall damage.

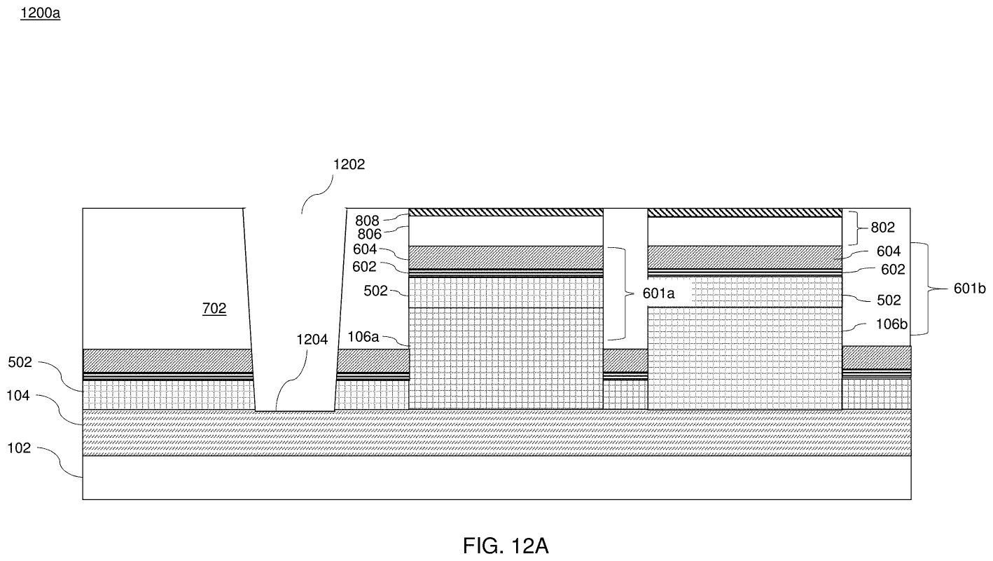

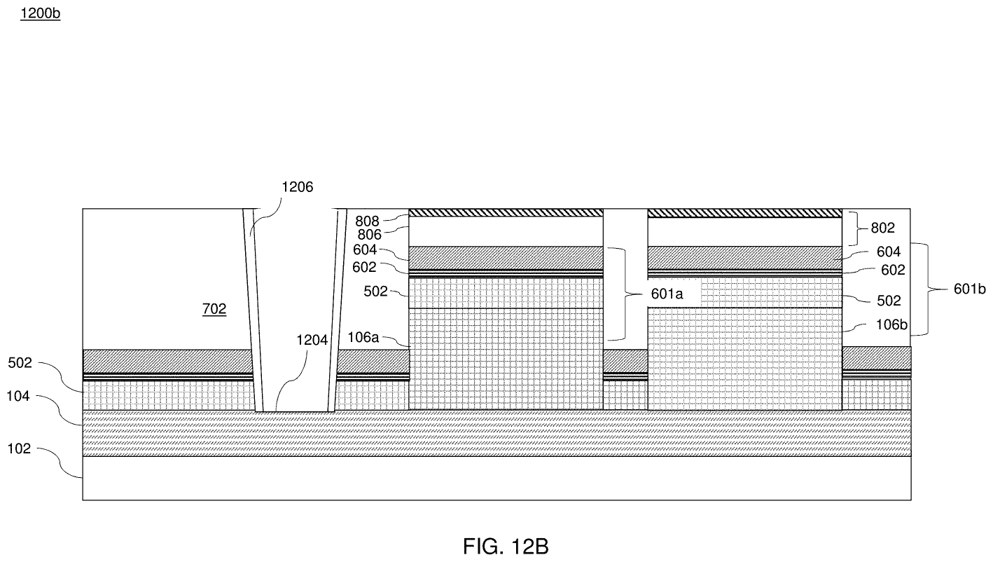

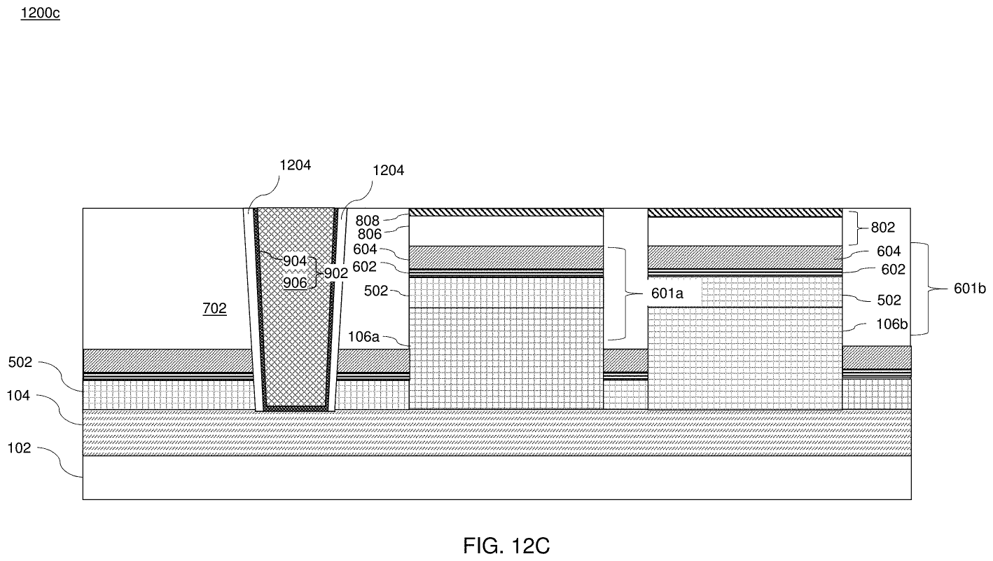

FIG. 12A is a vertical cross-sectional view of a further intermediate structure 1200a that may be used in the formation of LED structures, according to various embodiments. As shown in FIG. 12A, a via cavity 1202 may be formed through the dielectric matrix layer 702. For example, a photoresist layer (not shown) may be applied over the dielectric matrix layer 702, and may be lithographically patterned to form an opening therethrough. An anisotropic etch process may be performed to etch through the dielectric matrix layer 702 until a top surface 1204 of the buffer layer 104 is physically exposed to form the via cavity. In other embodiments, a plurality of via cavities may be formed such that each light emitting diode to be subsequently formed has a respective contact via structure. The photoresist layer may be subsequently removed, for example, by ashing.

FIG. 12B is a vertical cross-sectional view of a further intermediate structure 1200b that may be used in the formation of LED structures, according to various embodiments. In contrast to the embodiment of FIG. 9, however, an electrically insulating layer 1206 may be formed in the via cavity 1202 prior formation of a via contact structure 902. The intermediate structure 1200b may be formed from the intermediate structure 1200a by depositing the electrically insulating layer 1206 on surfaces of the via cavity 1202 of FIG. 12A. The electrically insulating layer 1206 may include silicon oxide, silicon nitride, or silicon oxynitride. The electrically insulating layer 1206 may be conformally deposited as a thin film. The electrically insulating layer 1206 is subsequently etched using an anisotropic etch process (e.g., a reactive ion etch) in a sidewall spacer etch process to remove horizontal portions of the electrically insulating layer 1206 from the exposed top surface 1204 of the buffer layer 104 and from the top surface of the dielectric matrix layer 702. This leaves sidewall spacer portions of the electrically insulating layer 1206 on the sidewalls of the via cavity 1202. The top surface 1204 of the buffer layer 104 is exposed in the via cavity 1202, as shown in FIG. 12B.

FIG. 12C is a vertical cross-sectional view of a further intermediate structure 1200c that may be used in the formation of LED structures, according to various embodiments. The intermediate structure 1200c may be formed by forming the contact via structure 902 using processes described above with reference to FIG. 9. Each contact via structure 902 may vertically extend through the dielectric matrix layer 702 and may contact the buffer layer 104 and the remaining sidewall spacer portions of the electrically insulating layer 1206. The presence of the electrically insulating layer 1206 is advantageous in that it may prevent or reduce electrical short circuits and leakage currents from the contact via structure 902 to surrounding portions of the intermediate structure 1200c.

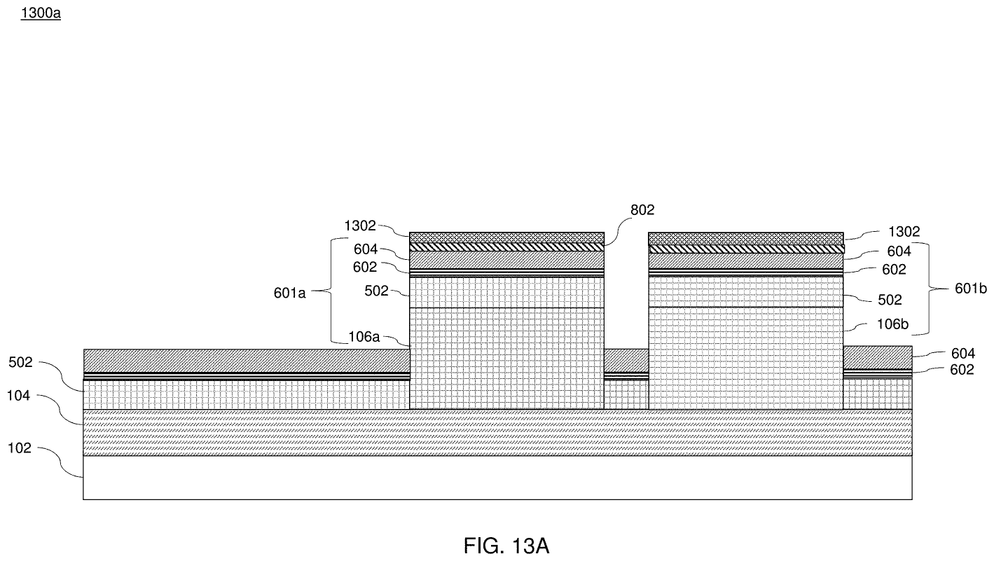

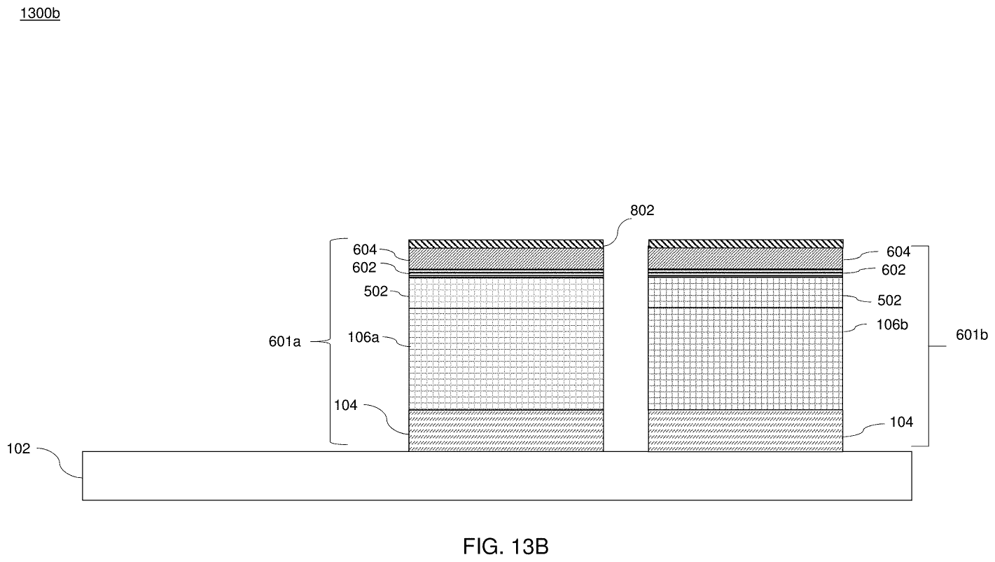

FIGS. 13A and 13B are vertical cross-sectional views of further intermediate structures 1300a and 1300b, respectively, that may be used in the formation of LED structures, according to various embodiments. The intermediate structure 1300a may formed by forming a patterned mask layer 1302 over the intermediate structure 600 of FIG. 6. The electrodes 802 may be formed over the intermediate structure 600 of FIG. 6 prior to forming the patterned mask layer 1302 over the electrodes 802. Alternatively, the electrodes 802 may be formed at a later step. For example, the patterned mask layer 1302 may be formed by depositing a photoresist material over the intermediate structure 600 of FIG. 6 or over the electrodes 802 located over the intermediate structure 600. The deposited photoresist material may then be patterned using photolithography techniques to form the patterned mask layer 1302 over the first vertical LED 601a and the second vertical LED 601b of FIG. 6. An anisotropic etch process (e.g., a reactive ion etch) may then be performed to remove portions of the active layer 602, the second-conductivity-type semiconductor material layer 604, the regrowth layer 502, and optionally the buffer layer 104 in the trench 404 and other areas between and adjacent to the first vertical LED 601a and the second vertical LED 601b, as shown in FIG. 13B. After the etch process has been completed, the patterned mask layer 1302 may then be removed by ashing or by dissolution in a solvent.

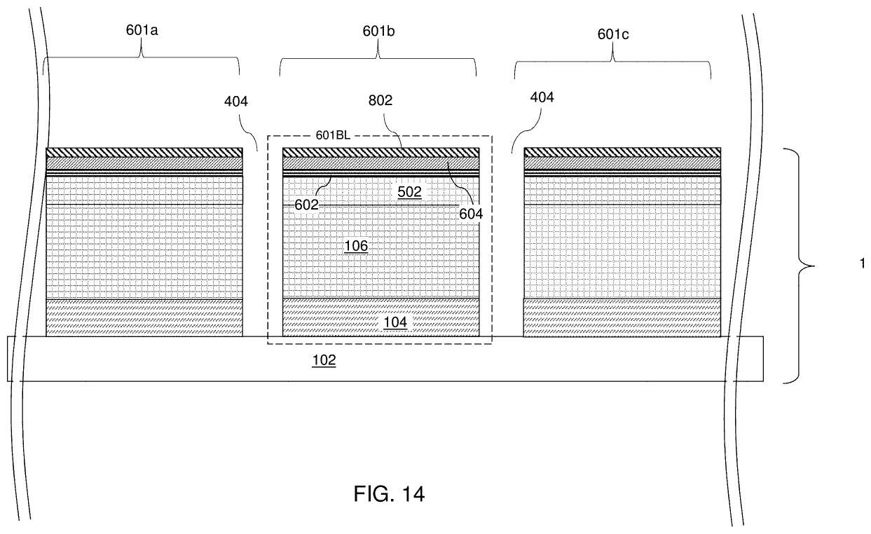

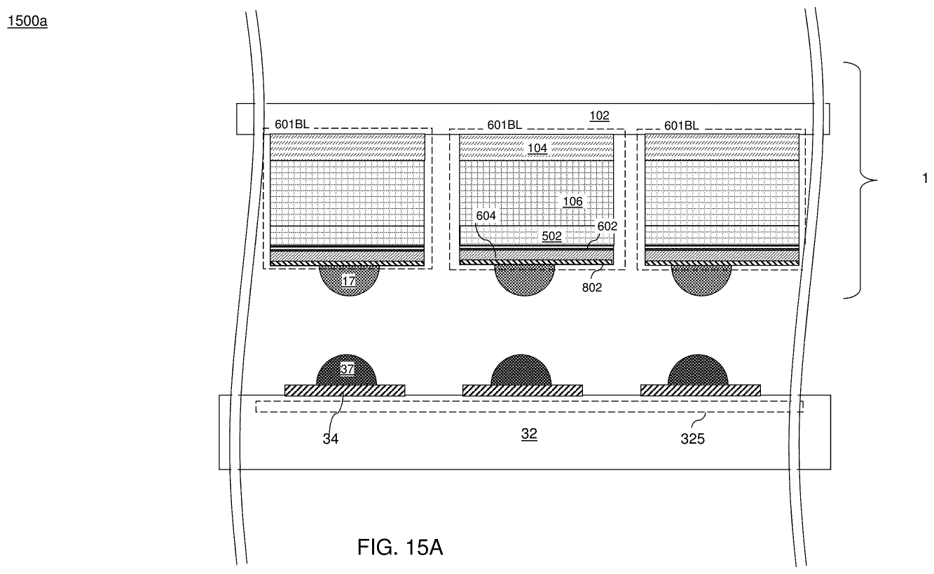

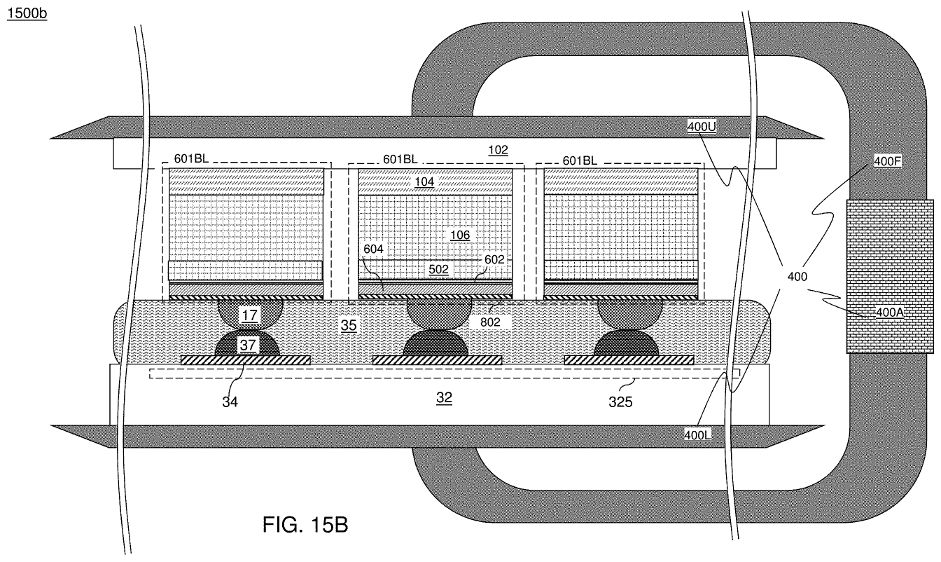

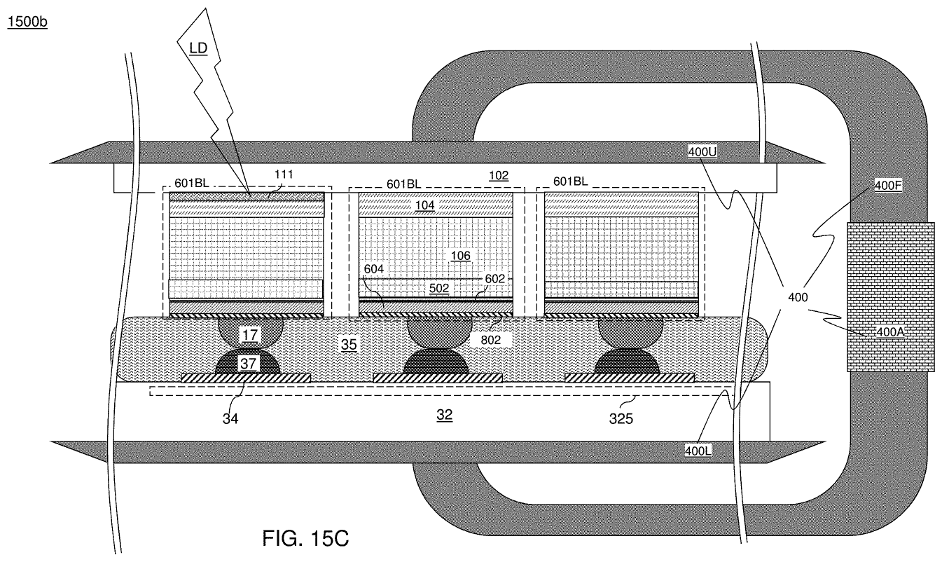

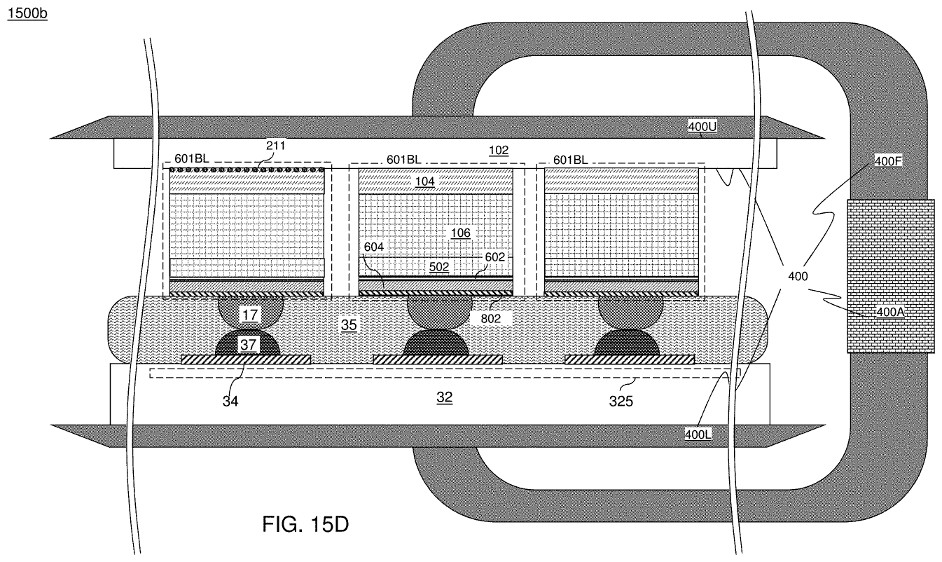

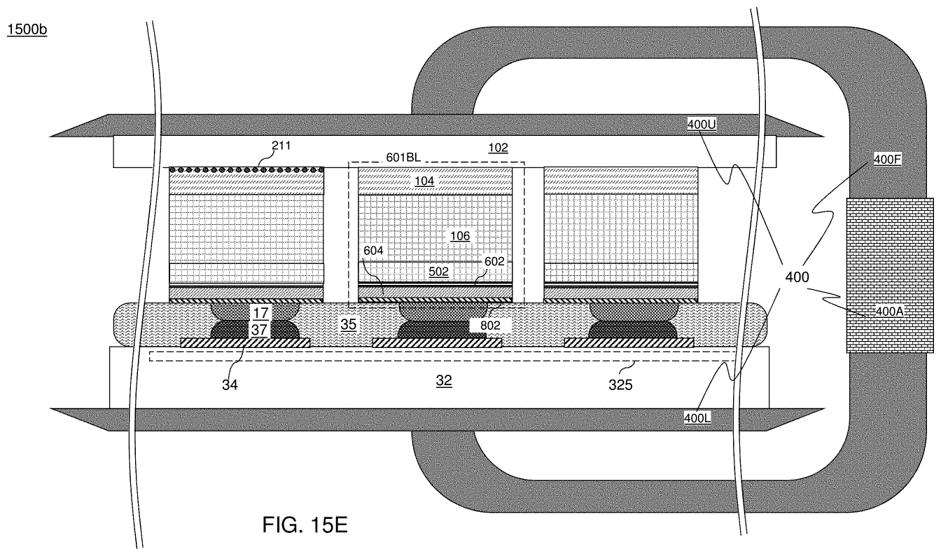

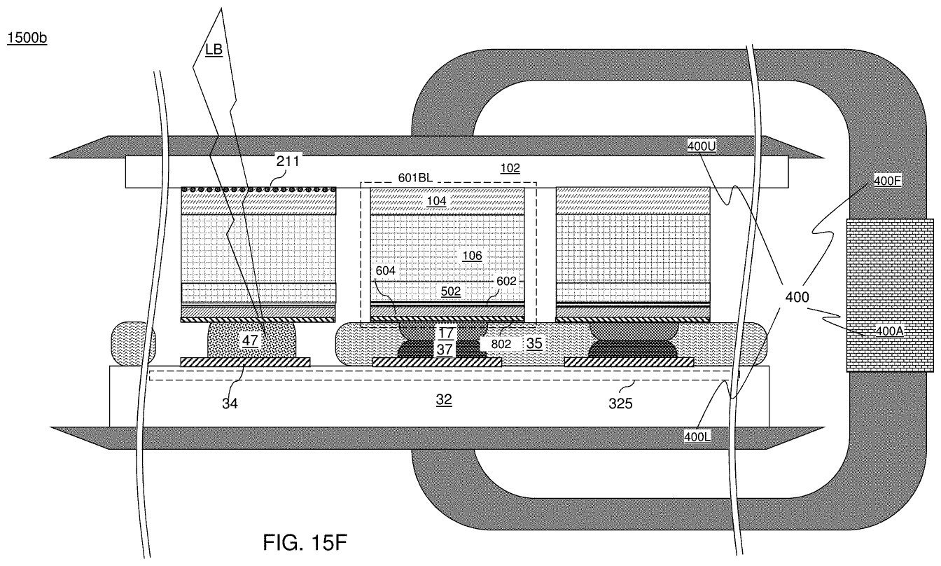

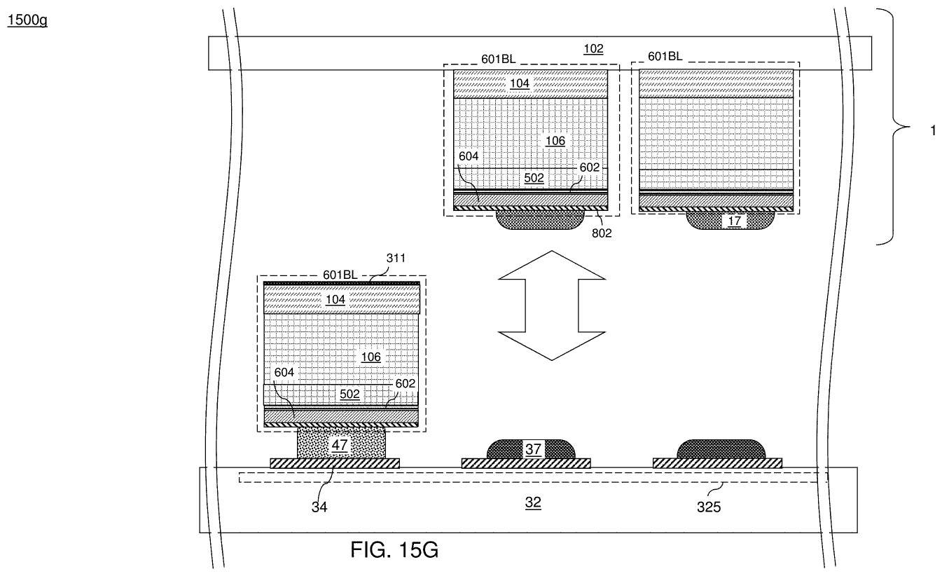

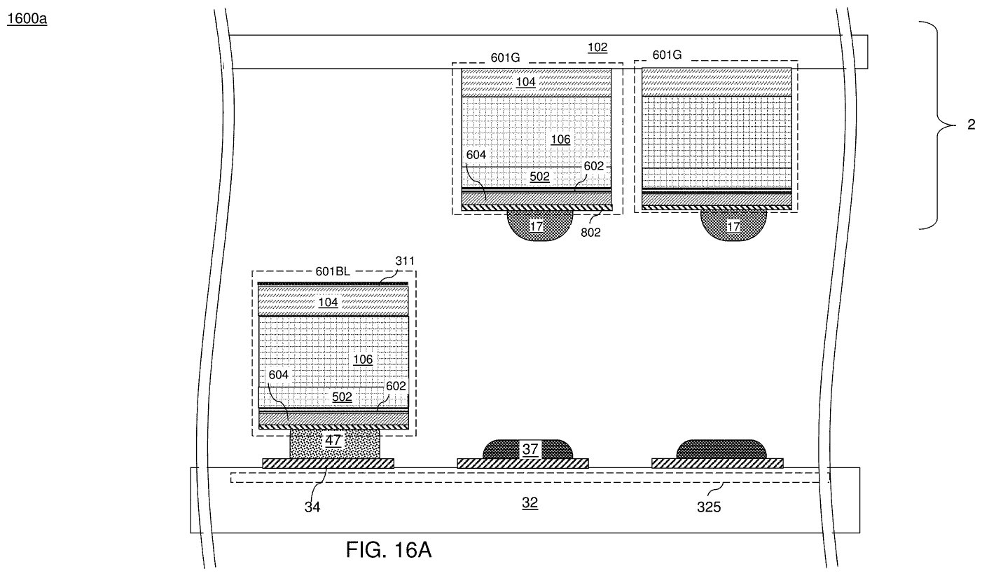

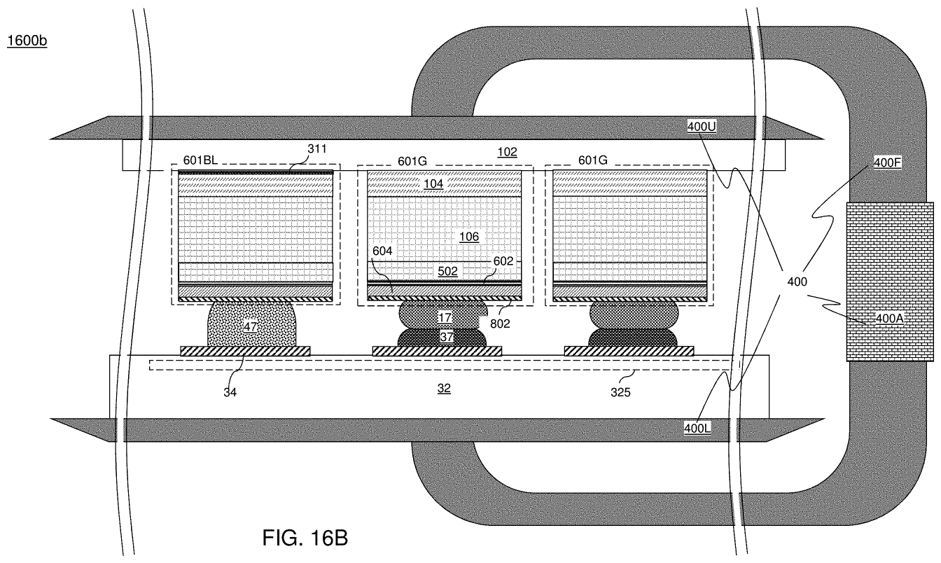

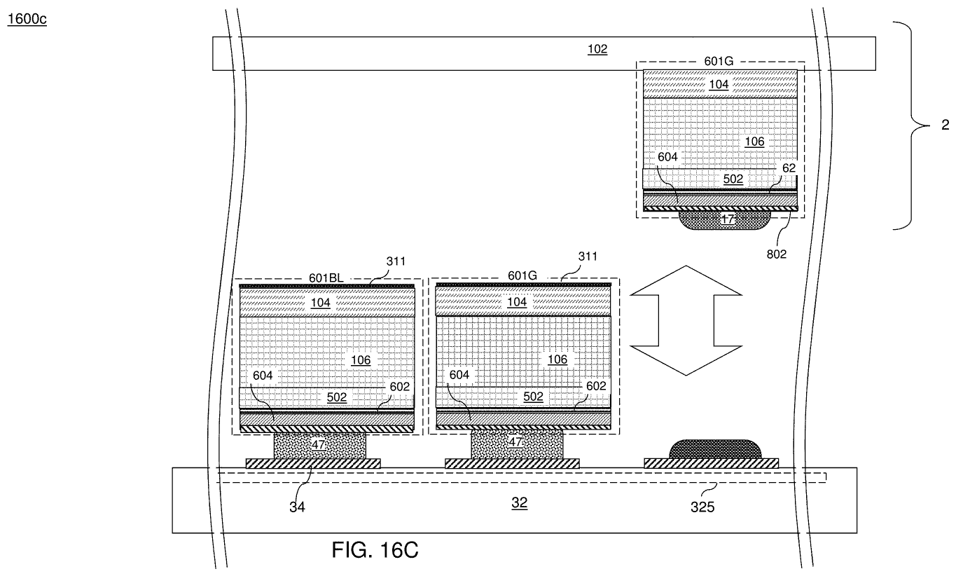

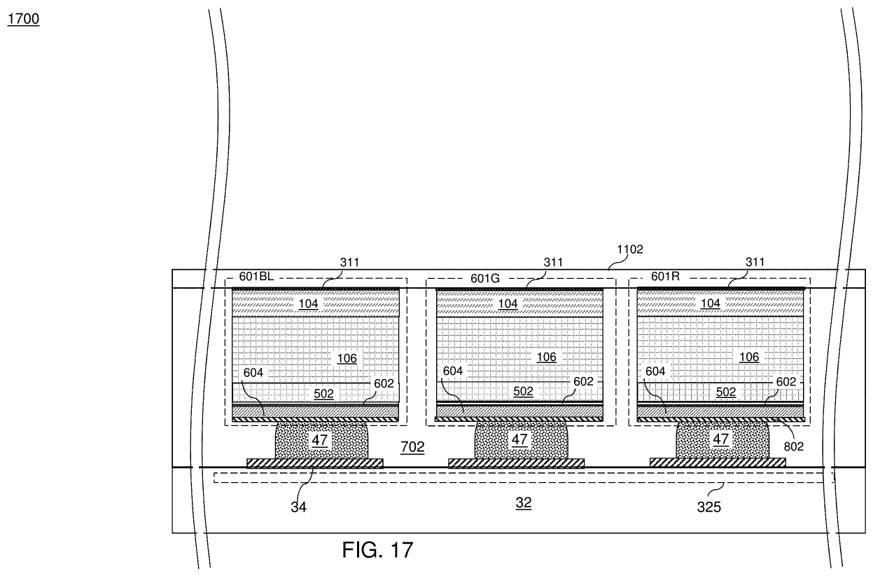

FIG. 14 illustrates a vertical cross sectional view of a source coupon 1 including a plurality of the above described light emitting diodes 601a, 601b, 601c separated by trenches 404, according to various embodiments. The light emitting diodes 601a, 601b, 601c may be formed using methods described above with reference to FIGS. 1 to 6, 13A, and 13B. Each of the light emitting diodes 601a, 601b, 601c may be configured to emit radiation having a narrow band of wavelengths with a peak at a specific wavelength. As such, each of the light emitting diodes 601a, 601b, 601c may emit light corresponding to a first color. For example, the light emitting diodes 601a, 601b, 601c may be configured to emit blue light, and are labeled 601BL. In other embodiments (e.g., see FIGS. 16A to 17), the light emitting diodes 601a, 601b, 601c may be configured to emit green light and are labeled 601G. In further embodiments (e.g., see FIG. 17), the light emitting diodes 601a, 601b, 601c may be configured to emit red light, and are labeled 601R. As described with reference to FIGS. 15A to 17, below, light emitting diodes (601BL, 601G, 601R) may be arranged on a backplane 32 to thereby form a plurality of subpixels of a pixel of a display device, with each pixel configured to emit a plurality of colors.

The first source coupon 1 may include a first substrate, which may comprise the above described support substrate 102. The first substrate 102 (may also be referred to as a first growth substrate or a first source substrate). First light emitting diodes 601BL are located on the first substrate 102, as described above. The first substrate 102 may be any suitable substrate on which LED layers may be grown, such as a single crystalline substrate. For example, the first substrate 102 may be a sapphire substrate. Each first light emitting diode 601BL may include the buffer layer 104, the first conductivity type semiconductor layer 106, and the regrowth layer 502, as described above with reference to FIG. 5. The active layer 602 may be located over the regrowth layer 502 and first conductivity type semiconductor layer 106 and the second conductivity type semiconductor layer 604 may be located over the active layer 602, as described above with reference to FIG. 6.

As described above with reference to FIGS. 1 to 4, the light emitting diodes 601BL may be formed such that a trench 404 separates adjacent light emitting diodes 601BL. The trenches 404 define an area associated with each first LED 601BL. Specifically, each continuous set of material layers overlying the first substrate 102 and laterally enclosed by a set of trenches 404 constitutes the first light emitting diode 601BL. In one embodiment, the trenches 404 may be formed in a lattice pattern to provide an array of first light emitting diodes 601BL, which may be a periodic array of first light emitting diodes 601BL. The first light emitting diodes 601BL may emit light at a first peak wavelength, such as a blue light having the first peak wavelength in the blue spectral range.

FIG. 15A is a vertical cross sectional view of an intermediate structure 1500a having the source coupon 1 of FIG. 14 positioned over a backplane 32 prior to attachment of light emitting diodes 601BL to the backplane 34, according to various embodiments. A diode-side bonding material portion 17 may be attached to the electrode 802 located over the second conductivity type semiconductor layer 604 in each of the first light emitting diodes 601BL. In one embodiment, the diode-side bonding material portions 17 may be solder material portions such as pure tin or an alloy of tin and indium.

The backplane 32 may include a substrate and a metal interconnect layer 325 formed on a front side surface of the substrate. In one embodiment, the substrate may include a plastic (e.g., polymer) substrate. Alternatively, the substrate may be a semiconductor substrate (e.g., silicon wafer) including a plurality of active matrix selector devices, such as field effect transistors in a CMOS configuration underlying the metal interconnect layer 325. In one embodiment, the metal interconnect layer 325 may include a plurality of metal interconnect structures located on the surface of the substrate and/or above the surface of the substrate and embedded in at least one insulating material. The metal interconnect layer 325 provides electrical connections between the light emitting diodes to be bonded onto the backplane 32 and input/output pins of the backplane 32.

Bonding pads 34 may be provided on a surface of the backplane 32 that overlies the metal interconnect layer 325. In one embodiment, the bonding pads 34 may be arranged as a two-dimensional periodic array or as a one-dimensional periodic array. The bonding pads 34 may include a bonding pad material such as gold, copper, nickel, titanium, titanium nitride, tungsten, tungsten nitride, another metal having a higher melting point than a solder material to be subsequently employed, alloys thereof, and/or layer stacks thereof. A backplane-side bonding material portion 37 may be attached to the bonding pads 34. In one embodiment, the backplane-side bonding material portions 37 may be solder material portions such as pure tin or alloy of tin and indium. The first source coupon 1 and the backplane 32 may be aligned such that a pair of a diode-side bonding material portion 17 and a backplane-side bonding material portion 37 face one another at every lattice point of the periodic array of the bonding pads 34.

FIG. 15B is a vertical cross sectional view of a further intermediate structure 1500b in which the backplane 32 and the first source coupon 1 are brought into contact with one another such that each facing pair of a diode-side bonding material portion 17 and a backplane-side bonding material portion 37 contact each other, according to various embodiments. Each of the diode-side bonding material portion 17 may have an areal overlap with a respective underlying backplane-side bonding material portion 37. In one embodiment, the area of the overlap may be at least 70%, such as more than 80% and/or more than 90%, of the area of the diode-side bonding material portion 17. In one embodiment, the geometrical center of each diode-side bonding material portion 17 may overlie a geometrical center of an underlying backplane-side bonding material portion 37.

Generally, at least one bonding material portion (17, 37) may be disposed between each vertically neighboring pair of a respective one of the bonding pads 34 and a respective one of the first light emitting diodes 601BL. In one embodiment, a pair of a diode-side bonding material portion 17 and a backplane-side bonding material portion 37 may be provided between each vertically neighboring pair of a respective one of the bonding pads 34 and a respective one of the first light emitting diodes 601BL. In one embodiment, the diode-side bonding material portions 17 may be omitted. In another embodiment, the backplane-side bonding material portions 37 may be omitted.

In an embodiment, a solder flux 35 may be applied between the backplane 32 and the first light emitting diodes 601BL such that the solder flux 35 laterally surrounds each bonding material portion (17, 37). The solder flux 35 may be any suitable liquid flux which reacts with tin oxide to leave metallic tin bonding material portions (17, 37). In one embodiment, a fixture, such as a clamp 400, may be employed to hold the assembly of the backplane 32 and the first source coupon 1 in place without lateral slippage. In an illustrative example, the clamp 400 may include an upper plate 400U that presses against the backside of one of the backplane 32 or the first source coupon 1, a lower plate 400L that presses against the backside of the other of the backplane 32 or the first source coupon 1, a frame 400F that includes mechanical support elements that holds the upper plate 400U and the lower plate 400L in place, and an adjustment unit 400A that adjusts the force applied to the upper plate 400U and/or to the lower plate 400L or adjusts the distance between the upper plate 400U and the lower plate 400L. The plate contacting the first source coupon 1, such as the upper plate 400U may include material transparent to UV, visible light or IR laser radiation and/or it may include a central opening such that laser beams may pass through it, while the upper plate 400U clamps only the edge of the first source coupon 1.

In an illustrative example, the backplane 32 and the first source coupon 1 may be held in place while a compressive force is applied to the assembly of the backplane 32, the bonding material portions (17, 37), and the first source coupon 1 along the vertical direction. The magnitude of the compressive force may be selected such that the bonding material portions (17, 37) are not deformed in a significant manner, that is, the bonding material portions (17, 37) maintain the shapes as provided prior to clamping, and without bonding the respective bonding material portions 17 and 37 to each other. In an illustrative example, if 100,000 pairs of a diode-side bonding material portion 17 and a backplane-side bonding material portion 37 are present between the backplane 32 and the first source coupon 1, then the magnitude of the compressive force applied by the clamp 400 may be in a range from 250 N to 400 N.

FIG. 15C is a vertical cross sectional view of the intermediate structure 1500b in which sequential laser irradiation process may be performed to selectively irradiate each buffer layer 104 that overlies a first light emitting diode 601BL to be subsequently transferred to the backplane 32 with a detachment laser beam LD, according to various embodiments. The set of all first light emitting diodes 601BL that are subsequently transferred to the backplane 32 is herein referred to as a first subset of the first light emitting diodes 601BL. The detachment laser beam LD performs a partial laser liftoff process used to partially lift off the first subset of the first light emitting diodes 601BL, and is herein referred to as a detachment laser irradiation process. Each buffer layer 104 of the first subset of the first light emitting diodes 601BL is sequentially irradiated with the detachment laser beam LD one by one. The lateral dimension (such as a diameter) of the detachment laser beam LD may be about the same as the lateral dimension of a first light emitting diode 601BL. Thus, each buffer layer 104 may be individually irradiated without causing significant compositional changes in neighboring buffer layers 104.

The detachment laser beam LD may have an ultraviolet wavelength or a wavelength in a visible light range, and may be absorbed by the gallium and nitrogen containing III-V compound semiconductor material of the irradiated buffer layers 104. Without wishing to be bound by a particular theory, it is believed that irradiation of the detachment laser beam LD onto a buffer layer 104 evaporates nitrogen atoms without evaporating, or with minimal evaporation of, gallium atoms. The irradiation thus tends to reduce the atomic percentage of nitrogen in a remaining material. The first source coupon 1 and the backplane 32 may be mechanically held in place by the clamp 400 during and after this process.

In one embodiment, and without being bound by a particular theory, it is believed that the irradiated subset of the buffer layers 104 within the first subset of the first light emitting diodes 601BL may be converted into gallium-rich drops 111. The gallium-rich drops 111 may consist of pure liquid gallium-rich drops or may include an alloy of gallium and nitrogen containing gallium at an atomic concentration greater than 55%, such as 60% to 99%.

FIG. 15D is a vertical cross sectional view of the intermediate structure 1500b of FIG. 15B in which the liquid gallium-rich drops 111 have solidified into solid gallium-rich material portions (e.g., pure gallium or gallium rich alloy particles or regions) 211 after the irradiation if the first source coupon 1 temperature is maintained below the melting temperature of gallium (e.g., 29.76° C.) or its alloy, according to various embodiments. In one embodiment, each remaining portion of the laser-irradiated buffer layer 104 (which is a subset of the buffer layers 104 within the first subset of the first light emitting diodes 601BL) may include gallium-rich material portions 211 (i.e., solid pure gallium or gallium rich alloy particles or regions). In one embodiment, the gallium-rich material portions 211 may include gallium atoms at an atomic concentration greater than 55%, such as 60% to 100%. The gallium-rich material portions 211 may have an average thickness in a range from 5 nm to 100 nm, such as from 10 nm to 50 nm, although lesser and greater thicknesses may also be employed.

Each gallium-rich material portion 211 may include a continuous material layer, or may include a cluster of ball-shaped material portions. The subset of the buffer layers 104 located within the second subset of the first light emitting diodes 601BL that are not subsequently transferred to the backplane 32 are not irradiated with the laser beam LD, and thus, remain as buffer layers 104, such as gallium nitride buffer layers having about 50 atomic percent gallium and thus a higher melting point than the gallium-rich material portions 211.

Since a backplane-side bonding material portion 37 and a diode-side bonding material portion 17 within each adjoining pair merely contact each other during the laser irradiation and are not bonded to each other, the mechanical shock from the laser irradiation is not transmitted to the backplane 32 that may include a relatively fragile polymer. Thus, the partial laser liftoff described above with respect to FIGS. 15C and 15D which forms the gallium-rich material portions 211 may cause little or no damage to the backplane 32 and to the electrically conductive elements (34, 325) on the backplane 32. Further, the partial laser liftoff process prevents damage to re-solidified bonding material portions in subsequent processing steps, such as the processing steps of FIG. 15F, because the bonding reflow happens after the partial laser liftoff.

FIG. 15E is a vertical cross sectional view of the intermediate structure 1500b of FIG. 15B in which the backplane 32 and the first source coupon 1 are pressed against one another with a greater force to thereby induce deformation of the bonding material portions (17, 37) (i.e., to coin the bonding material portions to smooth out any rough bonding surfaces). Thus, each mating pair of a respective diode-side bonding material portion 17 and a respective backplane-side bonding material portion 37 may be pressed against each other at a second pressure that is greater than the first pressure after conversion of the subset of the buffer layers 104 into the gallium-rich material portions 211. The second pressure is sufficient to form deformation of the diode-side bonding material portions 17 and the backplane-side bonding material portions 37. In an illustrative example, if 100,000 pairs of a diode-side bonding material portion 17 and a backplane-side bonding material portion 37 are present between the backplane 32 and the first source coupon 1, then a magnitude of the compressive force applied by the clamp 400 may be in a range from 500 N to 1,000 N.

FIG. 15F is a vertical cross sectional view of the intermediate structure 1500b of FIG. 15B in which a sequential localized laser irradiation process may be performed to induce reflow and subsequent bonding of each mating pair of a diode-side bonding material portion 17 and a backplane-side bonding material portion 37 that underlies the first subset of the first light emitting diodes 601BL to be transferred to the backplane 32. The laser irradiation induces bonding of the first subset of the first light emitting diodes 601BL to the backplane 32, and is herein referred to as a bonding laser irradiation process. The laser beam LB employed during the bonding laser irradiation process may have a photon energy that is less than the band gap of the III-V compound semiconductor materials (e.g., gallium and nitrogen containing materials) in the first light emitting diodes 601BL, and thus passes through the first light emitting diodes 601BL. For example, the laser beam LB employed during the bonding laser irradiation process may be an infrared laser beam such as a carbon dioxide laser beam having a wavelength of 9.4 microns or 10.6 microns.

The laser beam LB may sequentially irradiate each mating pair of a diode-side bonding material portion 17 and a backplane-side bonding material portion 37. Each irradiated pair of a diode-side bonding material portion 17 and a backplane-side bonding material portion 37 is heated to a reflow temperature at which the bonding materials (which may be solder materials) of the pair of the diode-side bonding material portion 17 and the backplane-side bonding material portion 37 reflow. Upon termination of the irradiation of the laser beam onto a mating pair of a diode-side bonding material portion 17 and a backplane-side bonding material portion 37, the reflowed material re-solidifies to provide a re-solidified bonding material portion 47. Each re-solidified bonding material portion 47 is bonded to a bonding pad 34 and the electrode 82 of a first light emitting diode 601BL.

Generally, the first subset of the first light emitting diodes 601BL may be bonded to a respective underlying one of the bonding pads 34 by localized laser irradiation onto a respective underlying set of at least one bonding material portion (17, 37), which are reflowed and re-solidify to form a re-solidified bonding material portion 47. In one embodiment, each mating pair of the diode-side bonding material portions 17 and the backplane-side bonding material portions 37 may be pressed against one another at the second pressure during the localized laser irradiation. Each first light emitting diode 601BL within the first subset of the first light emitting diodes 601BL may be bonded to the backplane 32, and each first light emitting diode 601BL within the second subset of the first light emitting diodes 601BL may remain not bonded to the backplane 32. The gallium-rich material portions 211 may provide a weak adhesion force between the first substrate 102 and a first conductivity type semiconductor layer 106. Since the first light emitting diodes 601BL are held in place by the gallium-rich material portions 211, a lower power laser beam LB may be used than in conventional bonding processes. This further reduces damage to the backplane 32. The solder flux 35 may be evaporated during irradiation with laser beam LB or may be poured out after this step.

FIG. 15G is a vertical cross sectional view of a further intermediate structure 1500g in which the first source coupon 1 and the backplane 32 are removed from the clamp 400 and heated to a temperature above the melting temperature of the gallium-rich material portions 211 but below the melting temperature of the amorphous buffer layers 104 (e.g., below the melting temperature of gallium nitride). For example, if the gallium-rich material portions 211 (e.g., see FIG. 15F) include pure gallium, then the temperature may be raised to at least 30 degrees Celsius, such as 35 to 50 degrees Celsius to thereby melt to the gallium-rich material portions 211 into gallium-rich drops 111 (e.g., see FIG. 15C). This may separate a first assembly of the backplane 32 and the first subset of the first light emitting diodes 601BL from a second assembly of the first substrate 102 and the second subset of the first light emitting diodes 601BL with or without applying a mechanical force. For example, the second assembly may be pulled apart from the first assembly with a force less than 100 N.

Optionally, a gallium-rich material portion 311 (such as re-solidified gallium-rich drops 111 or remnants of portion 211) may be located on a surface of a buffer layer 104 (e.g., see FIG. 15G). The gallium-rich material portion 311 may include gallium at an atomic concentration greater than 55%, which may be greater than 95%. In one embodiment, the gallium-rich material portions 311 may consist essentially of gallium, and may have a thickness in a range from 5 nm to 100 nm, such as from 10 nm to 50 nm. If a single color LED device is desired, then the fabrication process may end at the step shown in FIG. 15G. Alternatively, the steps shown in FIGS. 15A to 15G may be repeated to bond different color LEDs to the backplane 32 to form a multi-color display.

FIG. 16A is a vertical cross sectional view of a further intermediate structure 1600a in which a second source coupon 2 may be provided, which includes second light emitting diodes 601G located on a second substrate 102, according to various embodiments. Each of the second light emitting diodes 601G may include a respective additional buffer layer 104 at an interface with the second substrate 102. The second light emitting diodes 601G may be arranged in a pattern including vacancies that include a mirror image pattern of the first subset of the first light emitting diodes 601BL in the first assembly. In one embodiment, the second light emitting diodes 601G may emit light at a second peak wavelength that is different from the first peak wavelength. The second source coupon and the first assembly may be aligned to each other such that each first light emitting diode 601BL on the backplane 32 underlies a respective one of the vacancies in the second source coupon.

FIG. 16B is a vertical cross sectional view of a further intermediate structure 1600b in which the backplane 32 and the second source coupon 2 are brought into contact with one another, according to various embodiments. In this regard, the second light emitting diodes 601G may be disposed over the first assembly such that at least one additional bonding material portion (17, 37) is disposed between each vertically neighboring pair of a respective one of the bonding pads 34 and a respective one of the second light emitting diodes 601G. The second source coupon 2 may be aligned and clamped to the first assembly employing a clamp 400 using the processing step described above with respect to FIG. 15B. The solder flux 35 (not shown for clarity) may be used during these steps as well. A subset of the additional buffer layers 104 may be converted into additional gallium-rich material portions 211 (e.g., see FIG. 15D) by performing the processing steps of FIG. 15C and FIG. 15D on each additional buffer layer 104 within a first subset of the second light emitting diodes 601G to be subsequently transferred to the backplane 32.

The processing steps of FIGS. 15C to 15F may be subsequently performed to bond the first subset of the second light emitting diodes 601G to a respective underlying one of the bonding pads 34 by localized laser irradiation onto a respective underlying set of at least one additional bonding material portions (17, 37). Each irradiated pair of a diode-side bonding material portion 17 and a backplane-side bonding material portion 37 may be heated to a reflow temperature at which the bonding materials (which may be solder materials) of the pair of the diode-side bonding material portion 17 and the backplane-side bonding material portion 37 reflow. Upon termination of the irradiation of the laser beam onto a mating pair of a diode-side bonding material portion 17 and a backplane-side bonding material portion 37, the reflowed material may re-solidify to provide a re-solidified bonding material portion 47 (e.g., see FIG. 15F). Each re-solidified bonding material portion 47 is bonded to a bonding pad 34 and contact-level material layers 15 of a second light emitting diode 601G as shown, for example, in FIG. 16C.

FIG. 16C is a vertical cross sectional view of a further intermediate structure 1600c in which the second source coupon 2 is separated from the backplane 32 after a first subset of the second light emitting diodes 601G has been bonded to the backplane, according to an embodiment. In this regard, a third assembly of the backplane 32, the first subset of the first light emitting diodes 601BL, and the first subset of the second light emitting diodes 601G may be separated (i.e., detached) from a fourth assembly of the second substrate 102 and a second subset of the second light emitting diodes 601G that are not bonded to the backplane 32 by separating them at the additional gallium-rich material portions 211. A gallium-rich material portion 311 (such as a re-solidified gallium-rich layer) may be located on a surface of a first conductivity type semiconductor layer 106 of a second light emitting diode 601G.

FIG. 17 is a vertical cross sectional view of a further intermediate structure 1700 in which a subset of third light emitting diodes 601R has been bonded to the backplane 32, according to an embodiment. In this regard, a third source coupon (not shown) may be provided, which includes third light emitting diodes 601R located on a third substrate. Each of the third light emitting diodes 601R may include a respective additional buffer layer 104 at an interface with the third substrate. The third light emitting diodes 601R may be arranged in a pattern including vacancies that include a mirror image pattern of the first subset of the first light emitting diodes 601BL and the first subset of the second light emitting diodes 601G in the third assembly. In one embodiment, the third light emitting diodes 601R may emit light at a third peak wavelength that is different from the first peak wavelength and from the second peak wavelength.

The processing steps of FIGS. 15B to 15G may be performed to transfer a first subset of the third light emitting diodes 601R to the backplane 32. The backplane 32 may include an array of pixels to provide a direct view display device. Each pixel may include one or more of the LEDs (601BL, 601G, 601R). In one embodiment, the backplane 32 may be a display frame for a direct view display device, and each pixel of the direct view display device may include at least one red-light emitting diode (such as a third light emitting diode 601R) configured to emit light at a peak wavelength in a range from 620 nm to 750 nm, at least one green-light emitting diode (such as a second light emitting diode 601G) configured to emit light at a peak wavelength in a range from 495 nm to 570 nm, and at least one blue-light emitting diode (such as a first light emitting diode 601BL) configured to emit light at a peak wavelength in a range from 450 to 495 nm.

The above described dielectric matrix layer 702 is then formed between the light emitting diodes (601BL, 601G, 601R). The common electrode 1102 is then formed over the dielectric matrix layer 702 and in electrical contact with the buffer layer 104 side of the light emitting diodes (601BL, 601G, 601R).

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. A method of forming light emitting diodes, comprising:
forming a first-conductivity-type compound semiconductor layer over a substrate;
etching the first-conductivity-type compound semiconductor layer to form a first pillar structure and a second pillar structure without exposing the substrate between the first and the second pillar structures;
selectively growing a semiconductor active layer over the first and the second pillar structures; and
selectively growing a second-conductivity-type compound semiconductor layer on the semiconductor active layer.

2. The method of claim 1, further comprising selectively growing a semiconductor regrowth layer on the first pillar structure and the second pillar structure, wherein the semiconductor active layer is selectively grown on the semiconductor regrowth layer.

3. The method claim 2, wherein:
third portions of the semiconductor regrowth layer, the semiconductor active layer and the second-conductivity-type compound semiconductor layer are also formed in a trench located between the first pillar structure and the second pillar structure; and
a top surface of the third portion second-conductivity-type compound semiconductor layer is located below first and second portions of the semiconductor active layer located over the first and the second pillar structures, respectively.

4. The method of claim 2, wherein the first-conductivity-type compound semiconductor layer and the second-conductivity-type compound semiconductor layer each comprise a Group III-nitride material.

5. The method of claim 4, wherein:
the first-conductivity-type compound semiconductor layer comprises a single crystal n-type GaN and the second-conductivity-type compound semiconductor layer comprises a single crystal p-type GaN;
the semiconductor active layer comprises at least one InGaN quantum well;
each of the first pillar structure and the second pillar structure have a top surface that is a c-plane surface of the n-type GaN; and
the semiconductor regrowth layer comprises a n-type GaN layer that is lattice matched to a crystal structure of the first pillar structure and the second pillar structure and has a top c-plane surface.

6. The method claim 3, further comprising forming a compound semiconductor buffer layer over the substrate prior to forming the first-conductivity-type compound semiconductor layer.

7. The method claim 6, wherein:
the substrate comprises sapphire; and
the etching the first-conductivity-type compound semiconductor layer comprises etching the first-conductivity-type compound semiconductor layer to expose the compound semiconductor buffer layer in the trench between the first pillar structure and the second pillar structure without exposing the sapphire substrate in the trench between the first and the second pillar structures.

8. The method claim 1, wherein:
the first pillar structure, a first portion of the semiconductor regrowth layer located on the first pillar structure, a first portion of the semiconductor active layer located on the first portion of the semiconductor regrowth layer, and a first portion of the second-conductivity-type compound semiconductor layer located on the first portion of the semiconductor active layer comprise a first light emitting diode; and
the second pillar structure, a second portion of the semiconductor regrowth layer located on the second pillar structure, a second portion of the semiconductor active layer located on the second portion of the semiconductor regrowth layer, and a second portion of the second-conductivity-type compound semiconductor layer located on the second portion of the semiconductor active layer comprise a second light emitting diode.

9. The method claim 8, further comprising forming first electrodes over the first and the second portions second-conductivity-type compound semiconductor layer in the first and the second light emitting diodes.

10. The method claim 9, further comprising:
bonding the first electrodes to a backplane;
removing the substrate; and
forming a common second electrode over the first and the second pillar structures on an opposite side of the first and second light emitting diodes from the first electrodes.

11. The method claim 9, further comprising:
bonding the first electrode of the first light emitting diode to a backplane without bonding the first electrode of the second light emitting diode to the backplane; and
detaching the first light emitting diode from the substrate using laser lift off, while the second light emitting diode remains on the substrate.

12. The method claim 11, further comprising:
attaching a third light emitting diode and a fourth light emitting diode to the backplane;
filling a space between the first, third and fourth light emitting diodes with a dielectric matrix layer; and
forming a common second electrode over the first, second and third light emitting diodes.

13. A light emitting diode structure, comprising:
a first light emitting diode comprising a first portion of a first-conductivity-type compound semiconductor layer, a first portion of a semiconductor active layer located over the first portion of the first-conductivity-type compound semiconductor layer, and a first portion of a second-conductivity-type compound semiconductor layer located over the first portion of the semiconductor active layer;
a second light emitting diode comprising a second portion of the first-conductivity-type compound semiconductor layer, a second portion of the semiconductor active layer located over the second portion of the first-conductivity-type compound semiconductor layer, and a second portion of the second-conductivity-type compound semiconductor layer located over the second portion of the semiconductor active layer;
a trench separating the first light emitting diode and the second light emitting diode; and
a third portion of the semiconductor active layer and a third portion of the second-conductivity-type compound semiconductor layer located in the trench, wherein a top surface of the third portion second-conductivity-type compound semiconductor layer is located below the first and the second portions of the semiconductor active layer.

14. The light emitting diode structure of claim 13, further comprising:
a first portion of a semiconductor regrowth layer located between the first portion of the first-conductivity-type compound semiconductor layer and the first portion of the semiconductor active layer in the first light emitting diode;
a second portion of the semiconductor regrowth layer located between the second portion of the first-conductivity-type compound semiconductor layer and the second portion of the semiconductor active layer in the second light emitting diode; and
a third portion of the semiconductor regrowth layer located in the trench below the third portion of the semiconductor active layer.

15. The light emitting diode structure of claim 14, wherein the first-conductivity-type compound semiconductor layer and the second-conductivity-type compound semiconductor layer each comprise a Group III-nitride material.

16. The light emitting diode structure of claim 15, wherein:
the semiconductor regrowth layer comprises a single crystal n-type GaN layer having top c-plane surface;
the first-conductivity-type compound semiconductor layer comprises a single crystal n-type GaN;
the second-conductivity-type compound semiconductor layer comprises a single crystal p-type GaN; and
the semiconductor active layer comprises at least one InGaN quantum well.

17. The light emitting diode structure of claim 13, further comprising first electrodes located over the first and the second portions second-conductivity-type compound semiconductor layer in the first and the second light emitting diodes.

18. The light emitting diode structure of 17, further comprising:
first conductive bonding structures electrically connected to the first electrodes;
a dielectric matrix layer laterally surrounding the first and the second light emitting diodes; and
a backplane electrically connected to the first conductive bonding structures.

19. The light emitting diode structure of 18, further comprising:
a common second electrode located over the first and the second portions of the first-conductivity-type compound semiconductor layer;
a contact via structure vertically extending through the dielectric matrix layer and electrically contacting the common second electrode; and
a second conductive bonding structure electrically connecting the contact via structure to the backplane.

20. The light emitting diode structure of 13, wherein the first portion of the semiconductor active layer lacks sidewall dangling bonds or reactive ion etch induced sidewall damage.
